(19) United States
(12) Patent Application Publication
(10) Pub. No.: US 2026/0113005 A1
(43) Pub. Date: Apr. 23, 2026

(54) WIDE-RANGE SWITCHED-MODE POWER AMPLIFIER ARCHITECTURE

(71) Applicant: Massachusetts Institute of Technology, Cambridge, MA (US)

(72) Inventors: Xin Zan, Cambridge, MA (US); David J. Perreault, Cambridge, MA (US); Khandoker N. Rafa Islam, Cambridge, MA (US)

(73) Assignee: Massachusetts Institute of Technology, Cambridge, MA (US)

(21) Appl. No.: 19/118,083

(22) PCT Filed: Oct. 27, 2023
(86) PCT No.: PCT/US2023/078020

§ 371 Date: Apr. 3, 2025

Related U.S. Application Data
(60) Provisional application No. 63/381,337, filed on Oct. 28, 2022.

(51) Int. Cl. H03F 3/217

(52) U.S. Cl. CPC H03F 3/2171; H03F 2200/267; H03F 2200/451; H03F 2203/21157

(57) ABSTRACT

According to one embodiment, a power amplifier includes a plurality of switches and an output tank network. One or more of the switches are configured to generate one or more first intermediate waveforms having one or more first fundamental frequency components, and one or more of the switches are configured to generate one or more second intermediate waveforms by chopping the one or more first intermediate waveforms with controllable timing. The second intermediate waveforms have one or more second fundamental frequency components that are controllably reduced from those of the one or more first intermediate waveforms. The output tank network is configured to filter the one or more second intermediate waveforms to provide an output waveform to a load, the output waveform having one or more third fundamental frequency components. In some cases, all switches achieve zero voltage switching under different power and load conditions with resistive and reactive loads.

### CROSS-REFERENCE TO RELATED APPLICATIONS

This application claims the benefit under 35 U.S.C. § 119 of U.S. Provisional Patent Application No. 63/381,337 filed on Oct. 28, 2022, which is hereby incorporated by reference herein in its entirety.

### BACKGROUND

Switched-mode power amplifiers capable of wide operating ranges, including resistive load range and reactive load range and/or a wide range of power levels, are needed for plasma generation, wireless power transfer, dc-dc converters, communications, battery chargers, induction heating, radio-frequency (RF) welding, and RF power transmission among other applications. Moreover, such switched-mode power amplifiers—also known as RF inverters-must often provide high control bandwidth (i.e., fast response speed) to changes in load and/or desired power level.

### SUMMARY

Disclosed herein is a switched-mode power amplifier architecture that can efficiently and rapidly control RF power into a variable load impedance, including loads with variable resistive and reactive components. The architecture provides direct RF output voltage modulation to control power and a further control means such as frequency modulation, structural modulation, or phase-switched impedance modulation to accommodate variations in load impedance. Output power control into a variable load may be achieved while preserving zero-voltage switching (ZVS) of all inverter power devices, which is often important for high-frequency applications.

The disclosed power amplifier architecture can be adapted to leverage other existing modulation methods, including input/drain voltage modulation, load modulation, outphasing modulation, and phase-switched impedance modulation. The disclosed wide-range power amplifier architecture offers the ability to provide fast-response control of power over a wide range into a variable load impedance. While disclosed embodiments are directed to dc-to-ac power conversion (inversion), the general approach can also be applied to ac-to-dc power conversion (rectification).

The disclosed power amplifier architecture is related to the controlled-transformation matching network technique introduced in and can be realized through different circuit implementations. As examples of the general concepts sought to be protected herein, the three following circuits are described: the wide-range voltage-mode class-D power amplifier (six switches or three switches), the wide-range current-mode class-D power amplifier, and the wide-range class-E power amplifier; other related variations in keeping the approach can likewise be implemented.

The amplifier architecture uses a version of phase control (or “reverse” phase control) as a principal to control fundamental RF output amplitude, which is referred to as β modulation hereinafter. The β modulation applies one or more zero-state portions to intermediate AC or DC waveforms, including square-wave waveforms, sinusoidal waveforms, and half-sine waveforms (for example), thus enabling the fundamental output to be controlled. Unlike conventional topologies, the disclosed topology enables direct output voltage modulation while preserving zero-voltage switching for all devices and device transitions across a wide operating range. In some embodiments, dynamic frequency tuning (DFT) or other secondary control means (e.g., structural modulation or phase-switched impedance modulation) can be leveraged to address load impedance variations. The wide control range and fast response capability come from the topology, β modulation, and the secondary control means (e.g., dynamic frequency modulation). Practically, by introducing a zero state in an intermediate waveform for an electrical angle β, where βₘᵢₙ<β<βₘₐₓ, rapid control of RF power can be achieved over a wide range including variable resistive and reactive components. A secondary control means (e.g., dynamic frequency tuning) can be used in conjunction with an output tank Lₛ and Cₛ to compensate for reactive variations in the load, while preserving ZVS of the inverter devices.

According to one aspect of the present disclosure, a power amplifier includes a plurality of switches and an output tank network. One or more of the switches are configured to generate one or more first intermediate waveforms having one or more first fundamental frequency components. One or more of the switches are configured to generate one or more second intermediate waveforms by chopping the one or more first intermediate waveforms with controllable timing, the second intermediate waveforms having one or more second fundamental frequency components that are controllably reduced from those of the one or more first intermediate waveforms. The output tank network is configured to filter the one or more second intermediate waveforms to provide an output waveform to a load, the output waveform having one or more third fundamental frequency components.

In some embodiments, the one or more switches can be configured to chop the one or more first intermediate waveforms with controllable timing determined by an electrical angle.

In some embodiments, the one or more of the switches can be configured to generate the first intermediate waveforms are different from the one or more of the switches configured to generate one or more second intermediate waveforms. In some embodiments, the one or more of the switches can be configured to generate the one or more first intermediate waveforms and the one or more of the switches configured to generate one or more second intermediate waveforms include one or more switches in common.

In some embodiments, the output tank network can include a capacitor and inductor connected in series with the load.

In some embodiments, the plurality of switches can include at least two switches. In some embodiments, the at least two switches may be connected in series between a voltage source and ground. In some embodiments, the plurality of switches can include at least six switches. In some embodiments, a first three of the at least six switches can be connected series between a voltage and ground and at least a second three of the at least six switches can also connected series between a voltage and ground.

In some embodiments, the one or more first intermediate waveforms may include one or more square waves. In some embodiments, the one or more second intermediate waveforms can include one or more square waves. In some embodiments, the output waveform can be a sinusoidal waveform.

In some embodiments, the power amplifier can include one or more inductive networks configured to provide zero-voltage switching (ZVS) for the plurality of switches. In some embodiments, the one or more inductive networks can include the output tank network. In some embodiments, the one or more inductive networks can include an inductor connected in parallel with the output tank network. In some embodiments, the one or more inductive networks can include at least two inductive networks.

In some embodiments, the one or more switches may include at least two switches arranged as two inverter halves configured to be operated out of phase to provide a second intermediate waveforms taken differentially between the two inverter halves.

In some embodiments, the one or more second intermediate waveforms can include at least two second intermediate waveforms combined such that a direct current (DC) component and even harmonics of the at least two second intermediate waveforms cancel and the fundamental components of the at least two second intermediate waveforms reinforce to drive the load.

According to one aspect of the present disclosure, a system includes a power amplifier as described above and a controller configured to control the plurality of switches of the power amplifier.

In some embodiments, the controller may be configured to use at least one of: frequency modulation is to adjust for variations in reactance of the load; frequency modulation to control power, voltage or current delivered to the load; or beta modulation to control power, voltage or current delivered to the load.

It should be appreciated that individual elements of different embodiments described herein may be combined to form other embodiments not specifically set forth above. Various elements, which are described in the context of a single embodiment, may also be provided separately or in any suitable sub-combination. It should also be appreciated that other embodiments not specifically described herein are also within the scope of the following claims.

### BRIEF DESCRIPTION OF THE DRAWINGS

The manner of making and using the disclosed subject matter may be appreciated by reference to the detailed description in connection with the drawings, in which like reference numerals identify like elements.

FIG. 1 is a block diagram showing a wide-range switched-mode power amplifier system, according to some embodiments.

FIGS. 2A and 2B are schematic diagrams showing examples of a six-switch wide-range voltage-mode class-D power amplifier, according to some embodiments.

FIGS. 3A-C are graphs showing modulated dual polarity square-wave waveforms that can be generated within a six-switch wide-range voltage-mode class-D power amplifier, according to some embodiments.

FIG. 4 is a series of graphs showing control sequences that may be used with a wide-range voltage-mode class-D power amplifier, according to some embodiments.

FIGS. 5A-D are schematic diagrams showing circuit operation of a six-switch wide-range voltage-mode class-D power amplifier, according to some embodiments.

FIGS. 6A and 6B are schematic diagrams showing examples of a three-switch wide-range voltage-mode class-D power amplifier, according to some embodiments.

FIGS. 7A-C are graphs showing modulated single polarity square-wave waveforms that can be generated within a three-switch wide-range voltage-mode class-D power amplifier.

FIG. 8 is a schematic diagram showing a six-switch wide-range voltage-mode class-D power amplifier with switch capacitances, according to some embodiments.

FIGS. 9A-C are graphs showing modulated dual polarity square-wave waveforms that can be generated within a six-switch wide-range voltage-mode class-D power amplifier with switch capacitances, according to some embodiments.

FIG. 10 is a series of graphs showing control sequences that may be used with a wide-range voltage-mode class-D power amplifier with switch capacitances, according to some embodiments.

FIG. 10A is a series of graphs showing additional control sequences that may be used with a wide-range voltage-mode class-D power amplifier with switch capacitances, according to some embodiments.

FIGS. 11A-H are schematic diagrams showing circuit operation of a six-switch wide-range voltage-mode class-D power amplifier with switch capacitances, according to some embodiments.

FIGS. 12A and 12B are graphs showing dynamic frequency modulation that may be used with a wide-range switched-mode power amplifier, according to some embodiments.

FIG. 13 is a graph showing a relationship between power, β, and resistive load.

FIGS. 14A and 14B are graphs showing further relationships between power, B. and resistive load and reactive load.

FIGS. 15A-C are graphs showing modulated sinusoidal waveforms that may be used with a wide-range switched-mode power amplifier, according to some embodiments.

FIGS. 16A-D are graphs showing modulated half-sine waveforms that may be used with a wide-range switched-mode power amplifier, according to some embodiments.

FIGS. 17A and 17B are schematic diagrams showing examples of a wide-range class-E power amplifier without and with switch capacitances, respectively, according to some embodiments.

FIGS. 18A and 18B are control sequences and modulated half-sine waveforms that may be used in conjunction with a wide-range class-E power amplifier without and with switch capacitances, respectively, according to some embodiments.

FIGS. 19A and 19B are schematic diagrams showing examples of a wide-range current-mode class-D power amplifier with and without switch capacitances, respectively, according to some embodiments.

FIG. 20 is a series of graphs showing control sequences and modulated sinusoidal waveforms that may be used with a wide-range current-mode class D power amplifier, according to some embodiments.

FIG. 21A is a schematic diagram showing how dynamic frequency tuning can be used to manage the effect of varying load reactance by changing the operating frequency, according to some embodiments.

FIG. 21B is a schematic diagram showing how phase-switched impedance modulation can be used to manage the effect of varying load reactance by controlling the switch S₁, according to some embodiments.

FIG. 21C is a schematic diagram showing how structural modulation can be used to manage the effect of varying load reactance by controlling the switches, according to some embodiments.

FIG. 21D is a schematic diagram showing how a combination of dynamic frequency tuning, phase-switched impedance modulation, and structural modulation can be used to manage the effect of varying load reactance by changing the operating frequency and controlling the switches, according to some embodiments.

FIG. 22 is a schematic diagram showing an example of a wide-range voltage-mode class-D power amplifier with multiple output, according to some embodiments.

FIGS. 23A-E are graphs showing examples of modulated square-wave waveforms in β modulation with some control strategies.

The drawings are not necessarily to scale, or inclusive of all elements of a system, emphasis instead generally being placed upon illustrating the concepts, structures, and techniques sought to be protected herein.

### DETAILED DESCRIPTION

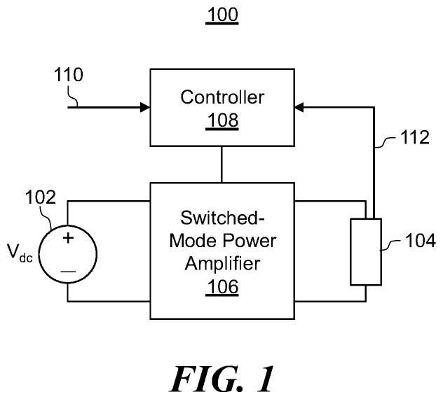

Referring to FIG. 1, an illustrative power amplifier system 100 can include a DC voltage source 102 (V_{dc}), a load 104, a switched-mode power amplifier 106 coupled between the voltage source 102 and the load 104, and a controller 108 coupled to the amplifier 106. Power amplifier 106 can include one or more switches and other electronic devices (e.g., capacitors and inductors) arranged in a particular circuit topology, detailed examples of which are described below in conjunction with several other figures.

Controller 108 may operate the switches of power amplifier 106 according to one or more control sequences and using β modulation as discussed in detail below. In some cases, controller 108 may also implement a secondary control scheme such as dynamic frequency modulation (i.e., changing the operating frequency of the power amplifier). More generally, the power, voltage, and/or current delivered to load 104 can be controlled using β modulation, frequency modulation, or both. Controller 108 can include hardware and/or software configured implement disclosed control schemes and, in some embodiments, can be provided as an application specific integrated circuit (ASIC). Disclosed power amplifier topologies and control schemes allow for wide operating ranges, including resistive load range and reactive load range and/or a wide range of power levels.

In some embodiments, and as shown in FIG. 1, controller 108 may be configured to adapt β and/or frequency modulation of amplifier 106 based on one or more inputs. For examples, controller 108 may be configured to receive commands via signal path 110 for setting β and/or switching frequency to desired values. As another example, controller 108 may be configured to receive feedback from load via signal path 112 and to adapt β and/or switching frequency based on said feedback. In some cases, systems 100 may include a VI probe or other type of sensor for measuring power, impedance, reactance, and/or another electrical characteristic of load 104, and the output of such a sensor may be used to provide feedback to controller 108. As yet another example, an adaptive feedforward technique may be used to adjust β and/or switching frequency.

In some embodiments, controller 108 may be configured to perform phase-switched impedance modulation, structural modulation, or both using structures and techniques described below.

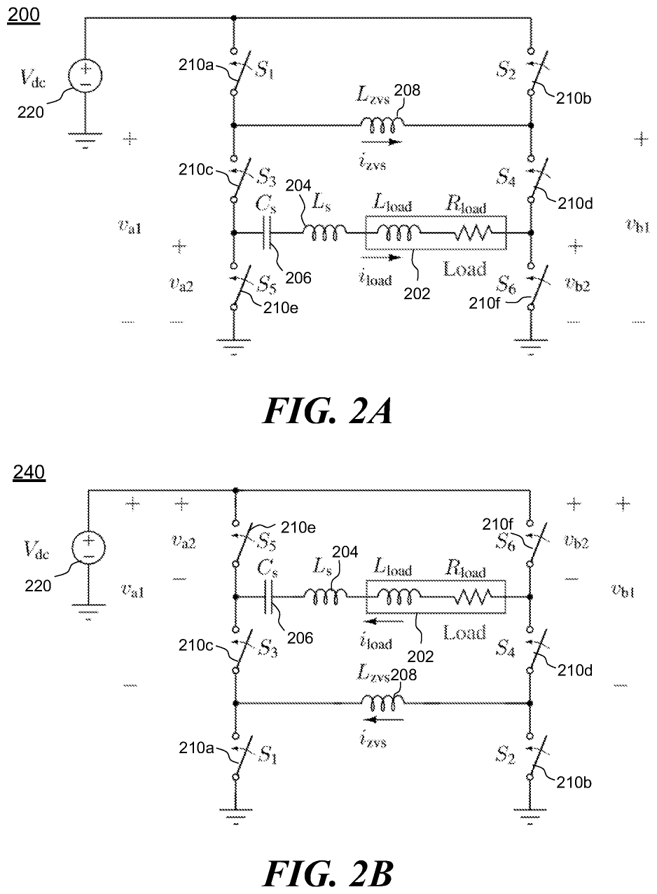

Turning to FIGS. 2A and 2B, according to some embodiments, a wide-range voltage-mode class-D power amplifier architecture can have six switches for a double-ended (or “differential”) version, or three switches for a single-ended version. The double-ended variant provides improved harmonic content in the output and higher power capability than the single-ended variant at the expense of a higher component count.

FIG. 2A shows an example of an inverter 200 according to a six-switch voltage-mode class-D power amplifier architecture. A load 202 is modeled as a series combination of a resistor R_{load} and an inductor L_{load}, which is in series with a first inductor 204 (Lₛ) and a capacitor 206 (Cₛ). A second inductor 208 (L_{ZVS}) is used to achieve the zero-voltage switching of switches, which will be illustrated later. The inverter 200 further includes a set of six total switches 210a-f (S₁₋₆) with a first set of three switches 210a, 210c, 210e (S₁, S₃, S₅) arranged in series and a second set of three switches 210b, 210d, 210f (S₂, S₄, S₆) also be arranged in series, as shown. A voltage source 220 (V_{dc}) may be connected as shown.

The six switches 210a-f may be configured to generate one or more first intermediate waveforms having one or more fundamental frequency components. A subset of the switches 210a-f can be configured to chop the one or more first intermediate waveforms with controllable timing to generate one or more second intermediate waveforms having fundamental frequency components that are controllably reduced from those of the first intermediate waveforms.

As shown in the figure, a first voltage vₐ₁ can be defined across a node connecting switches 210a. 210c (S₁, S₃) and ground; a second voltage v_{b1} can be defined across a node connecting switches 210b, 210d (S₂, S₄) and ground; a third voltage vₐ₂ can be defined across a node connecting switches 210c, 210e (S₃, S₅) and ground; and a fourth voltage v_{b2} can be defined across a node connecting switches 210d, 210f (S₄, S₆) and ground. With this arrangement, a first intermediate waveform can be taken as v_{ab1}(v_{a1-b1})=vₐ₁−v_{b1} and a second intermediate waveform can be taken as v_{ab2}(v_{a2-b2})=vₐ₂−v_{b2}. Equivalently, vₐ₁, v_{b1}, and v_{ab1} may both be referred to as a first intermediate waveform and vₐ₂, v_{b2}, and v_{ab2} may both be referred to as a second intermediate waveform.

The load 202, first inductor 204 (Lₛ), and capacitor 206 (Cₛ) may collectively be referred to as the “load branch.” In the architecture of FIG. 2A, the load branch is close to ground (i.e., can be connected to ground by a single switch 210e or 210f). In contrast. FIG. 2B shows a version of a six-switch inverter 240 wherein the load branch is close to voltage source 220 (V_{dc}) (i.e., can be connected to V_{dc} by a single switch 210e or 210f). Like elements of FIGS. 2A and 2B are indicated using like reference numerals.

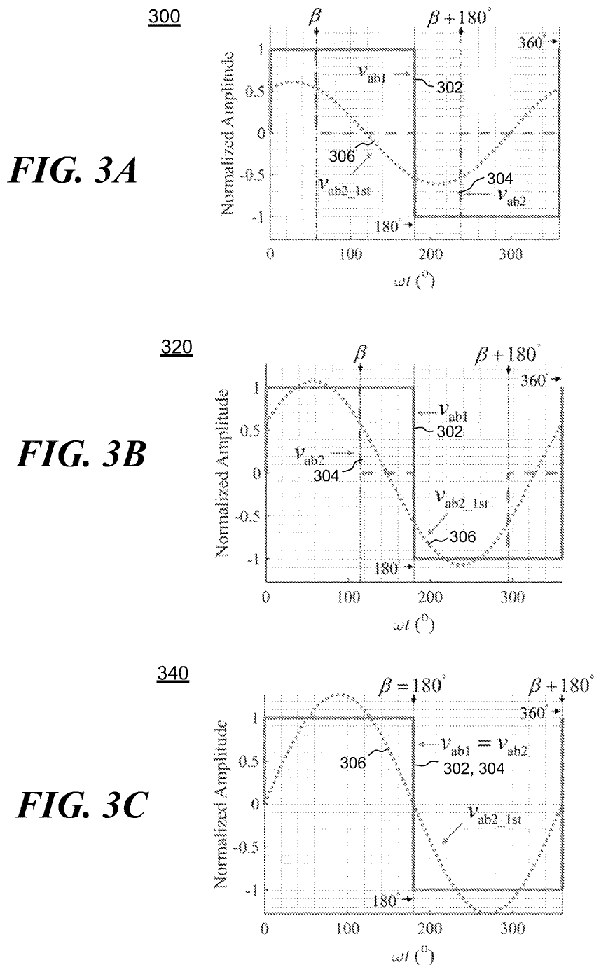

Inverter 200 of FIG. 2A and inverter 240 of FIG. 2B can be controlled such that voltage v_{ab1}(v_{a1-b1})=vₐ₁−v_{b1} is ideally a square wave, as shown in FIGS. 3A-C and approximately trapezoidal in practice, as shown in 9A-C. In the figures, v_{ab1}=vₐ₁−v_{b1} and v_{ab2}=vₐ₂−v_{b2}. As shown, phase control angle β is used to create a phase-controlled (or “chopped”) waveform v_{ab2}(v_{a2-b2})=vₐ₂−v_{b2}, based on voltage v_{a1-b1}; whose nonzero duration or duty ratio depends on β. In other words, β controls chopping from a first intermediate waveform 302 to a second intermediate waveform 304. The fundamental component v_{a2-b2_1st} of v_{a2-b2}, is controlled by β, which provides a means to control RF output power. In the case of an ideal square wave, where the rise and fall times of v_{a1-b1} and v_{a2-b2} are instantaneous, β has a usable range of 0°˜180°. Fundamentals of the second intermediate waveform 304 are filtered by the load branch (or “output tank network”) to produce sinusoidal output 306. In this and other examples disclosed herein, the output tank is comprised of Lₛ and Cₛ. Graphs 300, 320, and 340 show examples for three different control angles β.

The six-switch wide-range voltage-mode class-D power amplifier is related to the full-bridge voltage-mode class-D power amplifier but utilizes additional switches to achieve a wide output control range while preserving efficient operation.

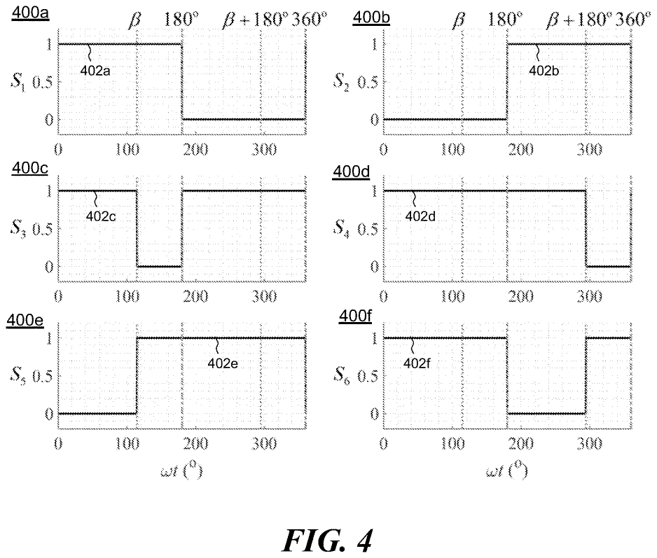

FIG. 4 shows control sequences (switch functions) of the six switches, where a switching function state of one (1) indicates a switch is on and state of zero (0) indicates a switch is off. Graphs 400a-f illustrate respective control sequences 402a-f for respective switches 210a-f (S₁₋₆) of FIGS. 2A and 2B.

As shown, S₁ and S₂ may operate (e.g., ideally operate) in a complementary fashion (i.e., neglecting dead time). In the first half cycle. S₁, S₄, and S₆ are on. S₃ also conducts during the first portion of the first half cycle but turns off at control angle β at which point S₅ turns on (neglecting dead time) and conducts while S₃ is off. In the second half cycle. S₂, S₃ and S₅ are held on. S₄ conducts for the first portion of the second half of the cycle, turning off at β+180°, at which point S₆ turns on (again, neglecting deadtime between S₄ and S₆).

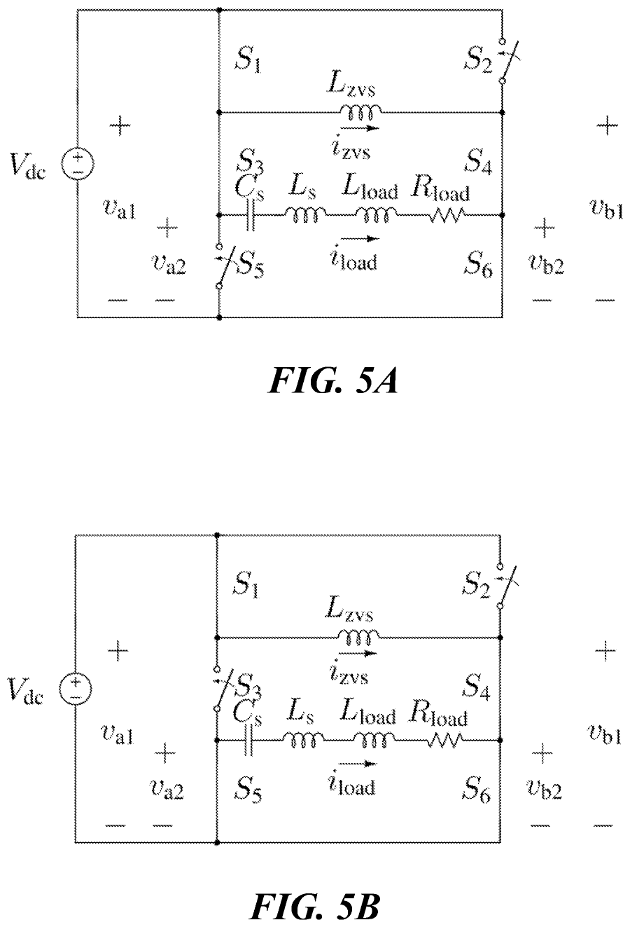

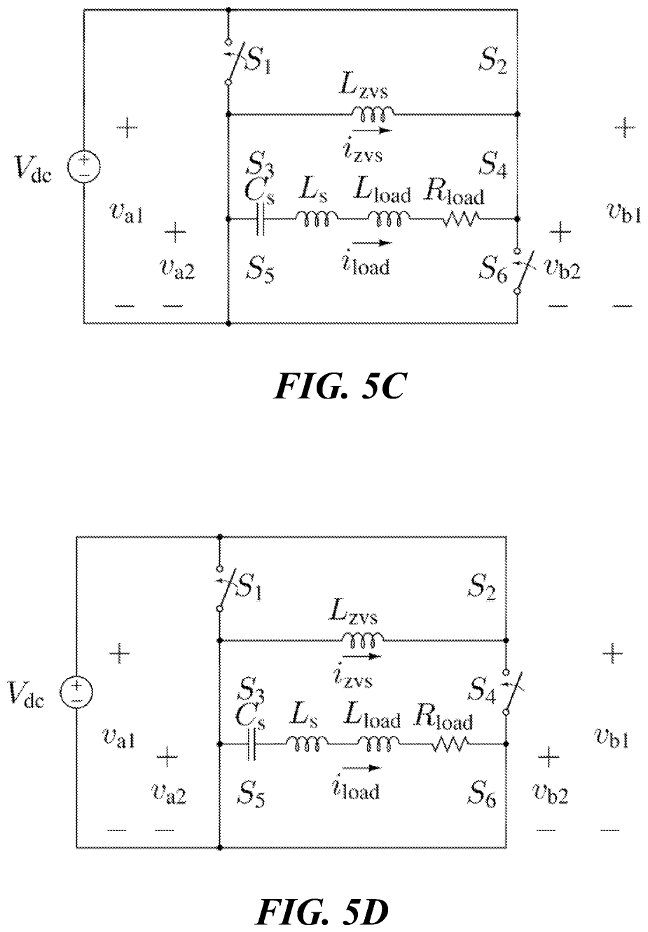

The circuit operation over these intervals is shown in FIGS. 5A-5D. As shown in FIG. 5A, between 0°˜β, vₐ₁=vₐ₂=V_{dc}, v_{b1}=v_{b2}=0 with switches S₁, S₃, S₄, and S₆ turned on. As shown in FIG. 5B, between β˜180°, vₐ₁=V_{dc}, vₐ₂=0, v_{b1}=v_{b2}=0 with switches S₁, S₄, S₅, and S₆ turned on. As shown in FIG. 5C, between 180°˜β+180°, vₐ₁=vₐ₂=0, v_{b1}=v_{b2}=V_{dc} with switches S₂, S₃, S₄, and S₅ turned on. As shown in FIG. 5D, between β+180°˜360°, vₐ₁=vₐ₂=0, v_{b1}=V_{dc}, v_{b2}=0 with switches S₂, S₃, S₅, and S₆ turned on.

Other related six-switch variants providing similar control capabilities can likewise be realized. For example, consider the inverter 240 of FIG. 2B where the load branch is connected between the top four switches. The top two switches are S₅ and S₆ (210e and 210f) while the bottom four switches are S₃, S₄, S₁, S₂ (210c. 210d. 210a. 210b), v_{a2-b2} is the modulated waveform of v_{a1-b1}(v_{ab1})=vₐ₁−v_{b1}, Where v_{a2-b2}(v_{ab2})=vₐ₂−v_{b2} is still the voltage across the load branch of Cₛ, Lₛ, L_{load}, and R_{load}, and v_{a1-b1} is the voltage across the inductor L_{ZVS}. With the control sequences in FIG. 4, the circuit in FIG. 2B can also modulate v_{a1-b1} as v_{a2-b2}, shown in FIG. 3.

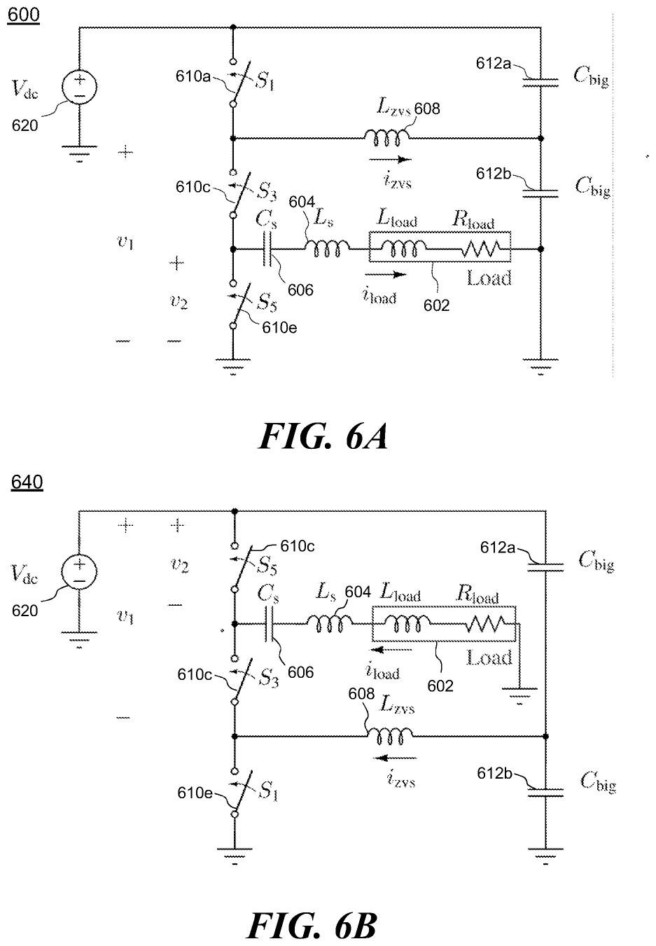

Three-switch “single-ended” versions of the wide-range voltage-mode class-D power amplifier can also be formulated, as illustrated in FIGS. 6A and 6B. This implementation creates a single polarity square wave in voltage v₁, and a modulated “rectangular” waveform of a different duty ratio in voltage v₂.

FIG. 6A shows an example of an inverter 600 according to a three-switch voltage-mode class-D power amplifier architecture. A load 602 is connected in series with a first inductor 604 (Lₛ) and a first capacitor 606 (Cₛ). A second inductor 608 (L_{ZVS}) is used to achieve the zero-voltage switching of switches. Inverter 600 further includes three switches 610a, 610c, 610e (S₁, S₃, S₅) arranged in series, as shown. A voltage source 620 (V_{dc}) may be connected as shown. Inverter 600 can also include second and third capacitors 612a, 612b (C_{big}) for voltage-second balance of L_{ZVS}.

As shown in the figure, a first voltage v₁ can be defined across a node connecting switches 610a, 610c (S₁, S₃) and ground and a second voltage 12 can be defined across a node connecting switches 610c, 610e (S₃, S₅) and ground. With this arrangement, v₁ may correspond to a first intermediate waveform and v₂ may correspond to a second intermediate waveform.

In the architecture of FIG. 6A, the load branch is close to ground. In contrast. FIG. 6B shows a version of a three-switch inverter 640 wherein the load branch is close to voltage source 620 (V_{dc}). Like elements of FIGS. 6A and 6B are indicated using like reference numerals.

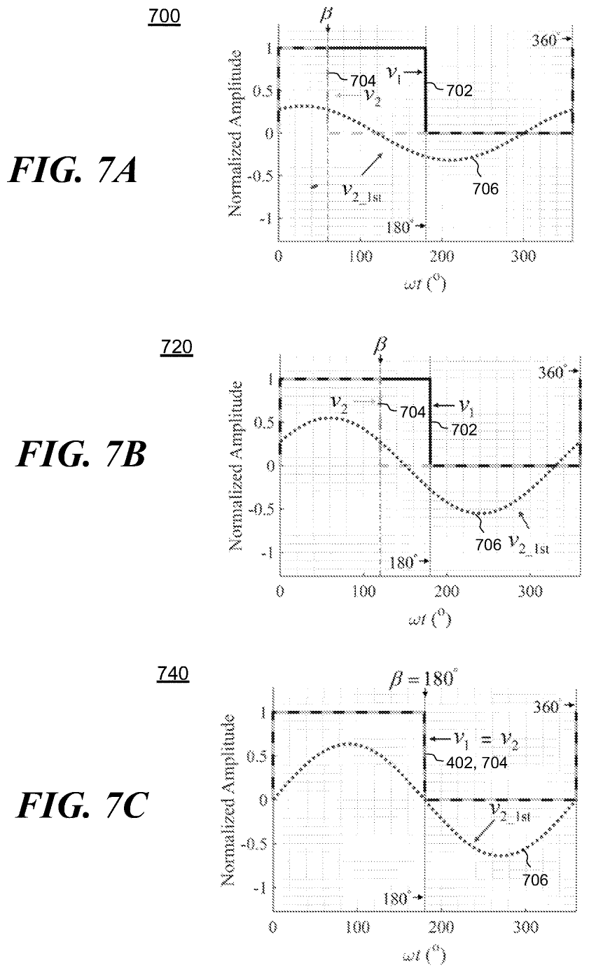

As illustrated in FIGS. 7A-C, inverter 600 of FIG. 6A and inverter 640 of FIG. 6B can be controlled such that voltage v₁ is (ideally) a square wave. As shown, phase control angle β is used to create a phase-controlled (or “chopped”) waveform v₂ whose nonzero duration or duty ratio depends on β. In other words, β controls chopping from a first intermediate waveform 702 to a second intermediate waveform 704. Fundamentals of the second intermediate waveform 704 are filtered by the output tank to produce sinusoidal output 706. Graphs 700, 720, and 740 show examples for three different control angles β.

The three-switch “single-ended” version of the circuit can provide power control using fewer switches but may result in even harmonics in the output voltage waveforms and less load power.

Control sequences 400, 420, and 440 of FIG. 4 can be used to control a three-switch inverter such as inverter 600 of FIG. 6A or inverter 640 6B. That is, whereas the six-switch version uses all the six control sequences, the three-switch version may use only those sequences corresponding to S₁, S₃, and S₅ for example.

What follows is an analysis of wide-range switched-mode power amplifiers according to the present disclosure. While the analysis is presented herein in terms of six-switch topologies, the subject matter sought to be protected herein extends to topologies with other numbers of switches, including but not limited to three-switch topologies.

For the waveforms in FIGS. 3A-3C, the peak amplitude and phase of the k^{th} harmonic of v_{a2-b2} can be calculated as

$$\vert {V}_{k} \vert = \frac{2 \sqrt{2}}{k π} {V}_{dc} \sqrt{1 - cos ( k β )} \qquad ( 1 )$$

$$and$$

$${ϕ}_{k} = - arctan \frac{1 - cos k β}{sin k β} \qquad ( 2 )$$

where harmonic order k equals 1 for v_{a2-b2_1st}, k is odd. The corresponding fundamental time-domain expression of v_{a2-b2} is v_{a2-b2_1st}=|V₁|cos(ωt+φ₁).

$$If β = π , \vert {V}_{k} \vert = \frac{4}{k π} {V}_{dc} and {ϕ}_{k} = - \frac{π}{2} ,$$

which are the amplitudes and phases of the square-wave Fourier series.

The average load power owing to the k^{th} harmonic component may be calculated as

$${P}_{k} = \frac{1}{2} {\vert {I}_{k} \vert}^{2} {R}_{load} = \frac{1}{2} \frac{{\vert {V}_{k} \vert}^{2} {R}_{load}}{{[ ω ( {L}_{S} + {L}_{load} ) - \frac{1}{ω {C}_{S}} ]}^{2} + {R}_{load}^{2}} \qquad ( 3 )$$

where ω is the operating frequency and |Vₖ| can be calculated from equation (1). For a high-quality output filter tank, the average load power P can be approximated as being fundamental power P₁.

For a given resistive load R_{load}, different values of β will result in different voltages applied to the load and hence different load power. To maintain the power range Pₘᵢₙ˜Pₘₐₓ for a given R_{load}, there is a β range βₘᵢₙ˜βₘₐₓ. There are minimum and maximum load resistance values Rₘᵢₙ and Rₘₐₓ that are the boundaries to achieve a minimum to maximum power range Pₘᵢₙ˜Pₘₐₓ for βₘᵢₙ≤β≤βₘₐₓ with a specified DC voltage V_{dc}.

Given a high quality-factor output tank Lₛ, Cₛ, a switching frequency can be selected that makes the net series reactance posed by the output tank Lₛ, Cₛ, and load inductance L_{load} provide a desired value, such that β and power range only depend on the resistive load (in the range Rₘᵢₙ˜Rₘₐₓ). In this way, for a given resistive component of the load impedance, similar circuit operation and waveforms can be maintained irrespective of the load reactance. That is, frequency modulation can be used to make the net reactance posed by the tank and the load be some desired values. Techniques for frequency selection/modulation are described in detail below. Additional techniques for achieving a wide operating range are also described in detail below.

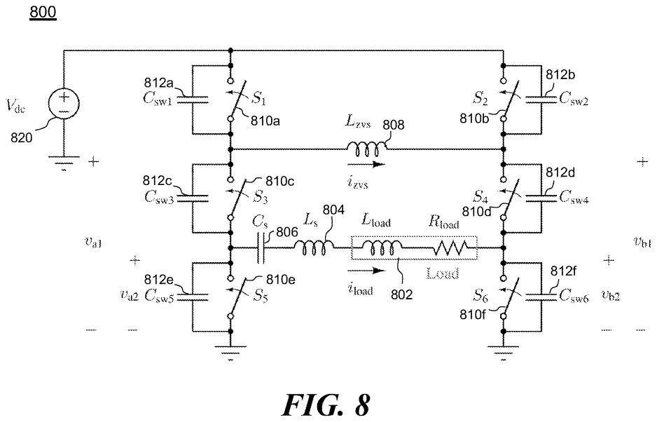

Turning to FIG. 8, in some practical applications, switches may be nonideal such that the voltages v_{a1-b1} and v_{a2-b2} may not rise and fall instantaneously. For example, switches have an output capacitance which may be modeled as a capacitance C_{sw} in parallel with the switch.

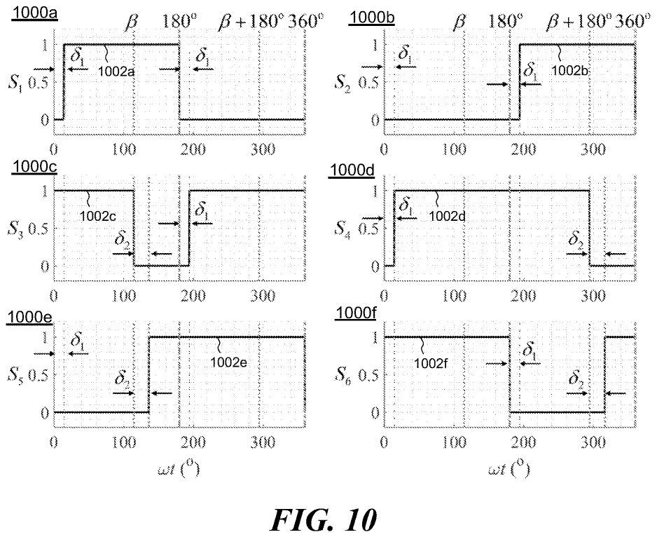

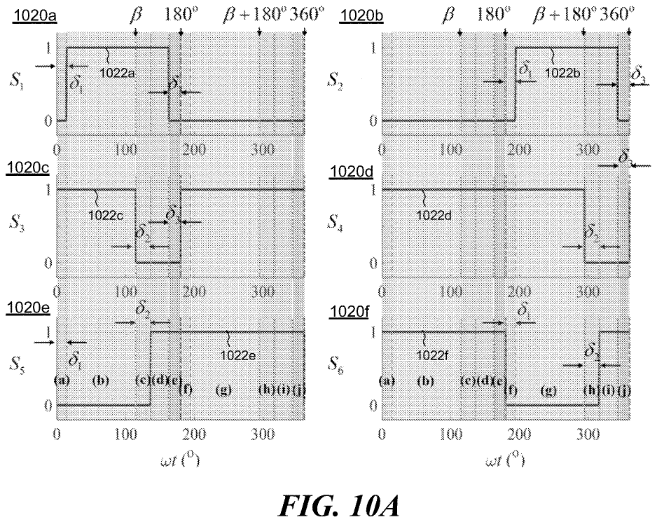

Illustrative inverter 800 includes a first inductor 804 (Lₛ) and a first capacitor 806 (Cₛ) connected in series with a load 802, along with a second inductor 808 (L_{ZVS}) for achieving the zero-voltage switching of switches. The inverter 800 further includes six switches 810a-f (S₁₋₆) each in parallel with a respective capacitor 810a-f (C_{sw1-6}). A voltage source 820 (V_{dc}) may be connected as shown. The switches may be operated, for example, using the control sequences of FIG. 10.

As a consequence of switch capacitances C_{sw1-6}, the circuit voltage waveforms have finite rise and fall times. To avoid switching loss at high frequency, zero-voltage switching (ZVS) may be implemented in a manner such that the switch voltage remains small at device turn-off, and devices are turned on only when they have small voltage across them. Thus, in some cases, despite providing modulated output waveforms, each switch can be turned on and off with zero voltage switching. Some transitions for ZVS switching in the circuits of FIG. 8 depend on the second inductor 808 (i.e., LVS inductor L_{ZVS}). Others depend upon the net inductance in the load series branch (Lₛ, Cₛ, L_{load}, and R_{load}). ZVS for this second group of transitions can also be implemented with an additional inductive reactance branch (not shown) placed in parallel with the load series branch.

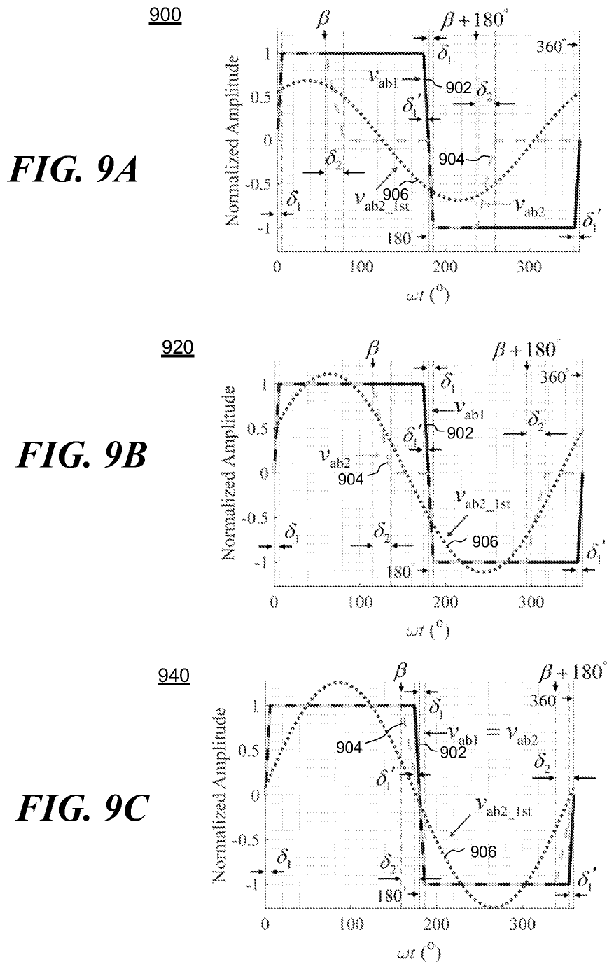

FIGS. 9A-C show waveforms that may be generated within the inverter 800 of FIG. 8. Graphs 900, 920, and 940 show examples for three different control angles β, with first intermediate waveform 902, second intermediate waveform 904, and sinusoidal output 906 being plotted in each graph. The modulation variable β is in the range of δ₁˜180°−δ₂, v_{ab1}=vₐ₁−v_{b1} and v_{ab2}=vₐ₂−v_{b2}. In FIG. 8. L_{zvs} relates to the ZVS switch voltage transition times δ₁ and δ₁′ in FIGS. 9A-C and the net inductance from the load series branch relates to the ZVS switch voltage transition time δ₁ and δ₂ in FIGS. 9A-C.

Because of switch capacitances (C_{sw1-6}), as shown in FIG. 8 and finite rise and fall times of voltages v_{a1-b1} and v_{a2-b2}, as shown in FIG. 9, a voltage rise time δ₁ and fall time δ₁′ in v_{a1-b1} (expressed in electrical angle) can be defined. δ₁ and δ₁′ of can be the same or different and do not need to depend heavily on loading conditions. The rise time of v_{a2-b2} follows v_{a1-b1} as δ₁ and its fall time δ₂ depends on the loading conditions.

The practical waveforms of v_{a1-b1}, v_{a2-b2}, and v_{a2-b2_1st} are shown in FIGS. 9A-C. Because of the existence of nonzero rise/fall times δ₁ and δ₂, |Vₖ| and φₖ become

$$\vert {V}_{k} \vert = \frac{2 \sqrt{2}}{{k}^{2} π} {V}_{dc} \sqrt{\frac{1 - cos ( k {δ}_{1} )}{{δ}_{1}^{2}} + \frac{1 - cos ( k {δ}_{2} )}{{δ}_{2}^{2}} + \frac{cos [ k ( β + {δ}_{2} ) ] + cos [ k ( β - {δ}_{1} ) ] - cos ( k β ) - cos [ k ( β + {δ}_{2} - {δ}_{1} ) ]}{{δ}_{1} {δ}_{2}}} \qquad ( 4 )$$

$$and$$

$${ϕ}_{k} = - arctan \frac{{δ}_{1} sin k β + {δ}_{2} sin ( k {δ}_{1} ) - {δ}_{1} sin [ k ( β + {δ}_{2} ) ]}{{δ}_{1} cos k β + {δ}_{2} cos ( k {δ}_{1} ) - {δ}_{2} - {δ}_{1} cos [ k ( β + {δ}_{2} ) ]} \qquad ( 5 )$$

respectively, where |Vₖ| and φₖ are the peak amplitude and phase of the k^{th} harmonic of v_{a2-b2}, respectively, k is odd.

The corresponding fundamental time-domain expression of v_{a2-b2} is

$${v}_{a 2 - b 2 \_ 1 st} = \vert {V}_{1} \vert cos ( ω t + {ϕ}_{1} ) \qquad ( 6 )$$

where |V₁| and φ₁ are the amplitude and phase from equations (4) and (5), respectively.

The average load power owing to the k^{th} harmonic component may be calculated as

$${P}_{k} = \frac{1}{2} {\vert {I}_{k} \vert}^{2} {R}_{load} = \frac{1}{2} \frac{{\vert {V}_{k} \vert}^{2} {R}_{load}}{{[ ω ( {L}_{S} + {L}_{load} ) - \frac{1}{ω {C}_{S}} ]}^{2} + {R}_{load}^{2}} \qquad ( 7 )$$

where ω is the operating frequency and |Vₖ| is from equation (4).

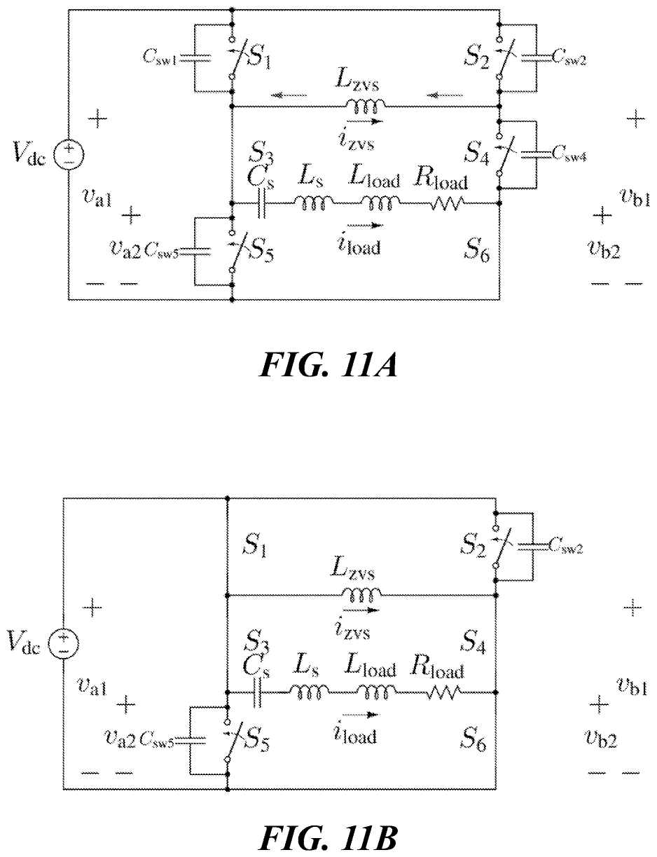

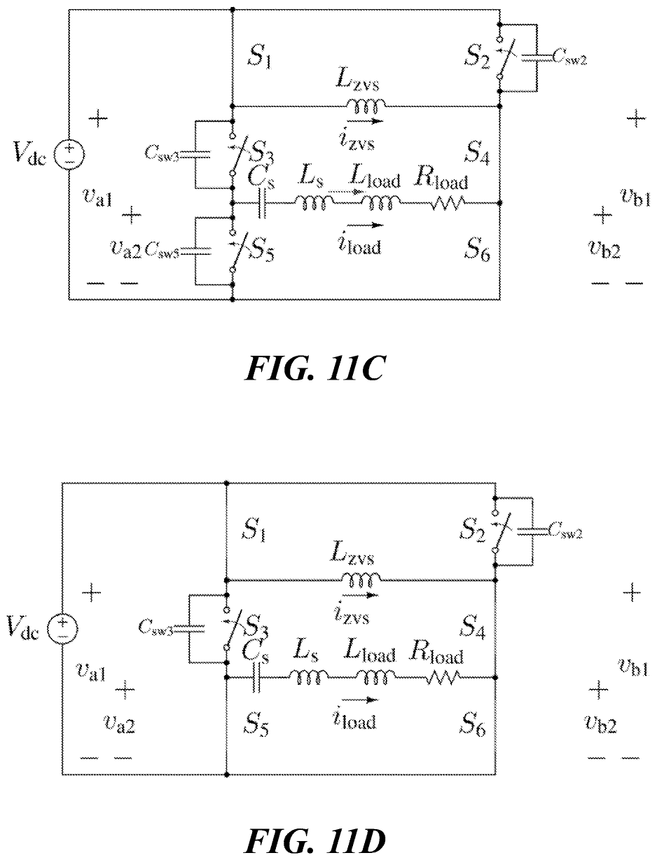

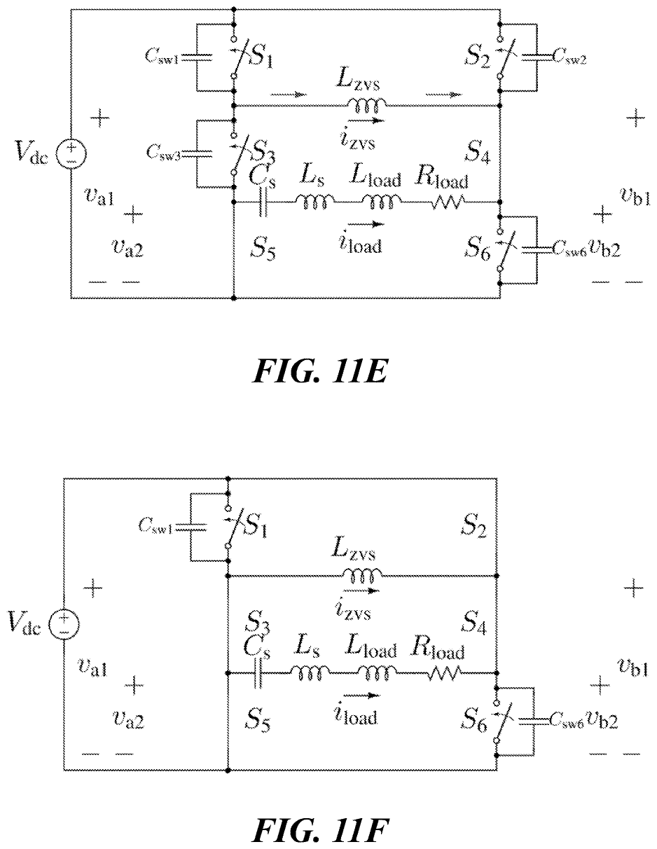

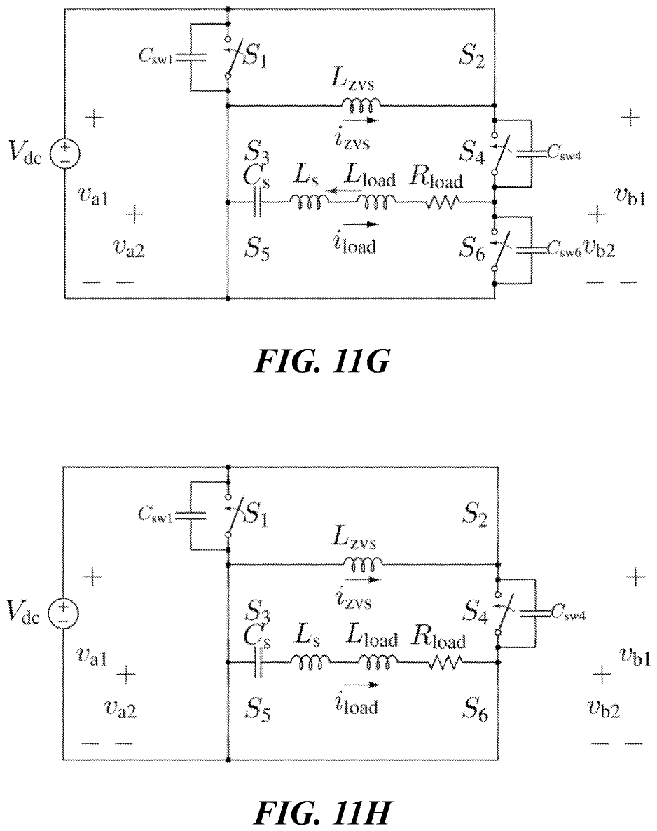

FIG. 10 shows control sequences that may be used for the wide-range voltage-mode class-D power amplifier with switched capacitances, such as inverter 800 of FIG. 8. FIGS. 11A-H illustrate circuit operation of such an amplifier. In FIG. 10, graphs 1000a-f illustrate control sequences 1002a-f for six switches S_{1 6} having capacitances.

As shown in FIG. 11A, between 0°˜δ₁, vₐ₁=vₐ₂, v_{b2}=0 with switches S₃ and S₆ turned on. As shown in FIG. 11B, between δ₁˜β, vₐ₁=vₐ₂=V_{dc}, v_{b1}=v_{b2}=0 with switches S₁, S₃, S₄ and S₆ turned on. As shown in FIG. 11C, between β˜β+δ₂, vₐ₁=V_{dc}, v_{b1}=v_{b2}=0 with switches S₁, S₄ and S₆ turned on. As shown in FIG. 11D, between β+δ₂˜180°, vₐ₁=V_{dc}, vₐ₂=0, v_{b1}=v_{b2}=0 with switches S₁, S₄, S₅ and S₆ turned on. As shown in FIG. 11E, between 180°˜180°+δ₁, vₐ₂=0, v_{b1}=v_{b2} with switches S₄ and S₅ turned on. As shown in FIG. 11F, between δ₁+180°˜β+180°, vₐ₁=vₐ₂=0, v_{b1}=v_{b2}=V_{dc} with switches S₂, S₃, S₄ and S₅ turned on. As shown in FIG. 11G, between β+180°˜β+δ₂+180° vₐ₁=vₐ₂=0, v_{b1}=V_{dc} with switches S₂, S₃ and S₅ turned on. As shown in FIG. 11H, between β+δ₂+180°˜360°, vₐ₁=vₐ₂=0, v_{b1}=V_{dc}, v_{b2}=0 with switches S₂, S₃, S₅ and S₆ turned on.

Compared to FIG. 4, the control sequences 1002a-f of FIG. 10 include dead time between switches to permit zero-voltage switching: S₁ turns on with a delay angle δ₁ after S₅ turns off under ZVS. During the dead-time interval 0<ωt<δ₁, vₐ₁=vₐ₂ increases to V_{dc} by i_{zvs} charging C₅ so that S₁ can have ZVS turn-on, which can be observed in FIG. 11A. Also, during this interval, i_{zvs} discharges C₄ so that S₄ can have ZVS turn-on. S₃ still turns off at β but S₅ turns on with a dead-time delay δ₂. During this dead-time delay, C₅ gets discharged by i_{load}, so that S₅ can have ZVS turn-on, as shown in FIG. 11C. (As previously mentioned, an additional inductive branch in parallel with the output network branch—not shown in FIG. 8—can also provide current for ZVS switching.) The turn off of S₁ and S₅ maintain unchanged without any delay as compared to the idealized case. The other three switches S₂, S₄, and S₆ operate 180° out of phase with the switches S₁, S₃, and S₅, respectively. As in the control sequence in FIG. 4, the AND of S₃ and S₅ is S₂ while AND of S₄ and S₆ is S₁ in FIG. 10, which is similar to that with ZVS class-D full-bridge operation.

Given the input DC voltage V_{dc}, it is desired to realize an output power range Pₘᵢₙ˜Pₘₐₓ for a load range Rₘᵢₙ˜Rₘₐₓ with an example reactive component of 0˜ωL_{load,max}. (A capacitive component to the load represented with an equivalent capacitance up to C_{load,max} could likewise be considered.) For example, consider an example with V_{dc}=300 V, Pₘᵢₙ=300 W, Pₘₐₓ=3000 W, a 4× resistive load range. i.e., Rₘₐₓ/Rₘᵢₙ=4, a reactive load component from j 0Ω to +j 15Ω, and the quality factor Q of the load branch (Cₛ, Lₛ, R_{load}, and L_{load}) is 5˜20, e.g., as determined by waveform purity and/or frequency range considerations. With given V_{dc}=300 V and power range Pₘᵢₙ=300 W˜Pₘₐₓ=3000 W, Qₘᵢₙ=5 for the series branch (Lₛ, Cₛ, L_{load}, and R_{load}), and center frequency f_{c}=13.56 MHz, parameters can be determined as follows.

FIG. 10A shows additional control sequences that may be used for the wide-range voltage-mode class-D power amplifier with switch capacitances, such as inverter 800 of FIG. 8. In FIG. 10A, graphs 1020a-f illustrate control sequences 1022a-f for six switches S₁₋₆ having capacitances. In contrast to the control sequences of FIG. 10, the control sequences 1022a-f of FIG. 10A include an additional dead time between switches, namely delay angle 83. This results in ten (10) different operating regions labeled (a)-(j) in FIG. 10A.

The disclosed wide-range power amplifier architecture is able to maintain ZVS for all inverter devices across load and power conditions; this is achieved by charging and discharging switch capacitances C_{sw} by i_{zvs} and i_{load} during dead times δ₁, δ₂, and δ₃.

Modeling i_{zvs} and i_{load} can be important for predicting ZVS conditions. Because the voltage across L_{zvs} is approximately a square wave (albeit with nonzero rise and fall times, as seen in FIG. 5, the current flow through L_{zvs} is an approximately symmetric triangle waveform that can be expressed as:

$${i}_{ZVS} = \{ \begin{matrix}\frac{2 {I}_{ZVS , pk}}{π} ω t - {I}_{ZVS , pk} , 0 + k \cdot 2 π \leq ω t < π + k \cdot 2 π \\ - \frac{2 {I}_{ZVS , pk}}{π} ω t + 3 {I}_{ZVS , pk} , π + k \cdot 2 π \leq ω t < 2 π + k \cdot 2 π\end{matrix} \qquad ( 8 )$$

$$with {I}_{ZVS , rms} = \frac{1}{\sqrt{3}} {I}_{ZVS , pk} and {I}_{ZVS , pk} = \frac{{V}_{dc} {T}_{s}}{4 {L}_{ZVS}} .$$

As long as the quality factor Q of the load branch is high enough, for example, Q=5, the load current i_{load} can be represented as

$${i}_{load} = {I}_{load , pk} cos ( ω t + {ϕ}_{1} - {ϕ}_{load} ) \qquad ( 9 )$$

$$where {I}_{load , pk} = \frac{\vert {V}_{1} \vert}{\sqrt{{R}_{load}^{2} + {X}_{net}^{2}}} and tan {ϕ}_{load} = \frac{{X}_{net}}{{R}_{load}}$$

|V₁| is the fundamental component. e.g., from equation (1).

ZVS can be important for high-frequency and very-high-frequency power conversion. For practical voltage-mode class D power amplifiers, there are dead times in control sequences as seen in FIG. 10 and FIG. 10A to enable switch capacitances to losslessly charge and discharge, so that the switches can have zero-voltage turn-on. In some cases, three dead-times: δ₁, δ₂, and δ₃ may be considered in the wide-range voltage-mode class D power amplifier.

Regarding δ₁, consider the commutation of current from S₅ to S₁ with S₃ held on. During δ₁, vₐ₁=vₐ₂. The combination of i_{zvs} and i_{load} charge C_{sw5} and discharge C_{sw1}. S₁ turns on at zero voltage when vₐ₁=vₐ₂=V_{dc}. Assume vₐ₁=vₐ₂=v₁(t),

$${i}_{Csw 1} + {i}_{Csw 5} = - {i}_{ZVS} - {i}_{load} \qquad ( 10 )$$

$$where$$

$${i}_{Csw 1} = {C}_{sw 1} \frac{d ( {v}_{1} - {v}_{dc} )}{dt} = {C}_{sw 1} \frac{{d v}_{1}}{dt}$$

$$and$$

$${i}_{Csw 5} = {C}_{sw 5} \frac{d ( {v}_{1} - 0 )}{dt} = {C}_{sw 5} \frac{{d v}_{1}}{dt} .$$

With the integration during δ₁,

$${\int }_{0}^{{V}_{dc}} ( {C}_{sw 1} + {C}_{sw 5} ) {d v}_{1} = - {\int }_{0}^{{δ}_{1} / ω} ( {i}_{ZVS} + {i}_{load} ) dt . \qquad ( 11 )$$

The precise solution can be derived from

$$ω ( {C}_{sw 1} + {C}_{sw 5} ) {V}_{dc} = - {\int }_{0}^{{δ}_{1}} [ {i}_{ZVS} ( ω t ) + {i}_{load} ( ω t ) ] d ( ω t ) . \qquad ( 12 )$$

Regarding i_{zvs}(ωt)≈i_{zvs}(0)=−I_{zvs,pk} and i_{load}(ωt)≈i_{load}(0)=I_{load,pk} cos(φ₁−φ_{load}) from equations (8) and (9) during δ₁, a linear approximation can be

$$ω ( {C}_{sw 1} + {C}_{sw 5} ) \frac{{V}_{dc}}{{δ}_{1}} = {I}_{ZCS , pk} - {I}_{load , pk} cos ( {ϕ}_{1} - {ϕ}_{load} ) . \qquad ( 13 )$$

Assuming C_{sw1}=C_{sw5}=C_{sw} (i.e., equal effective switch capacitances),

$${δ}_{1} = \frac{2 ω {C}_{sw} {V}_{dc}}{\frac{{V}_{dc} {T}_{S}}{4 {L}_{ZVS}} - \frac{\vert {V}_{1} \vert}{\sqrt{{R}_{load}^{2} + {X}_{net}^{2}}} cos ( {ϕ}_{1} - arctan \frac{{X}_{net}}{{R}_{load}} )} \qquad ( 14 )$$

where |V₁| can be calculated from equation (1) without considering the dead times for simplicity.

Then

$${δ}_{1} = \frac{2 ω {C}_{SW}}{\frac{{T}_{S}}{4 {L}_{ZVS}} - \frac{\frac{2 \sqrt{2}}{π} \sqrt{1 - cos β}}{\sqrt{{R}_{load}^{2} + {X}_{net}^{2}}} cos ( {ϕ}_{1} - arctan \frac{{X}_{net}}{{R}_{load}} )} \qquad ( 15 )$$

For ZVS turn-on of S₁, there is no requirement on the current direction of i_{load} as long as I_{zvs,pk}>I_{load,pk} cos(φ₁−φ_{load}). δ₁ is almost load independent.

Regarding δ₂, consider commutation of current from S₃ to S₅ with S₁ held on, i_{load} charges C_{sw3} and discharges C_{sw5}. S₅ turns on at zero voltage when vₐ₂=0. Assuming vₐ₂=v₂(t),

$${i}_{C s w 3} + {i}_{C s w 5} = {i}_{l o a d} \qquad ( 16 )$$

$$where$$

$${i}_{C s w 3} = {C}_{s w 3} \frac{d ( {V}_{d c} - {v}_{2} )}{d t} = - {C}_{s w 3} \frac{{dv}_{2}}{dt}$$

$$and$$

$${i}_{C s w 5} = {C}_{s w 5} \frac{d ( 0 - {v}_{2} )}{d t} = - {C}_{s w 5} \frac{{dv}_{2}}{d t}$$

With the integration during 82,

$${\int }_{{V}_{d c}}^{0} - ( {C}_{s w 3} + {C}_{s w 5} ) d {v}_{2} = {\int }_{β / ω}^{( β + {δ}_{z} ) / ω} {i}_{load} ( t ) dt . \qquad ( 17 )$$

The precise solution can be derived from

$$ω ( {C}_{s w 3} + {C}_{s w 5} ) {V}_{d c} = {\int }_{β}^{( β + {δ}_{2} )} {i}_{load} ( ω t ) d ( ω t ) \qquad ( 18 )$$

Regarding i_{load}(ωt)≈I_{load}(β)=I_{load,pk} cos(β+φ₁−φ_{load}) from equations (8) and (9) during δ₂, a linear approximation can be made

$$ω ( {C}_{s w 3} + {C}_{sw 5} ) \frac{{V}_{d c}}{{δ}_{2}} = {I}_{load , pk} cos ( β + {ϕ}_{1} - {ϕ}_{load} ) \qquad ( 19 )$$

$$Similarly ,$$

$${δ}_{2} = \frac{2 ω {C}_{s w}}{\frac{\frac{2 \sqrt{2}}{π} \sqrt{1 - cos β}}{\sqrt{{R}_{load}^{2} + {x}_{n e t}^{2}}} cos ( β + {ϕ}_{1} - arctan \frac{{x}_{net}}{{R}_{load}} )} \qquad ( 20 )$$

where it is again assumed all switch capacitances are equal.

For ZVS turn-on of S₅, i_{load}(β) has to be positive. δ₂ is load dependent.

Regarding δ₃, consider commutation of current from S₁ to S₃ with S₅ held on, i_{zvs} charges C_{sw1} and discharges C_{sw3}. S₃ turns on at zero voltage when vₐ₁=0. Assuming vₐ₁=v₃(t),

$${i}_{Csw 1} + {i}_{Csw 3} = {i}_{zvs} \qquad ( 21 )$$

$$where$$

$${i}_{Csw 1} = {C}_{sw 1} \frac{d ( {V}_{d c} - {v}_{3} )}{d t} = - {C}_{sw 1} \frac{{dv}_{3}}{dt}$$

$$and$$

$${i}_{Csw 3} = {C}_{sw 3} \frac{d ( 0 - {v}_{3} )}{d t} = - {C}_{sw 3} \frac{{dv}_{3}}{d t} .$$

With the integration during 83,

$${\int }_{{V}_{d c}}^{0} - ( {C}_{s w 1} + {C}_{s w 3} ) d {v}_{3} = {\int }_{π / ω - {δ}_{3} / ω}^{π / ω} {i}_{z v s} ( t ) d t . \qquad ( 22 )$$

The precise solution can be derived from

$$ω ( {C}_{s w 1} + {C}_{s w 3} ) {V}_{d c} = {\int }_{π - {δ}_{3}}^{π} {i}_{z v s} ( ω t ) d ( ω t ) . \qquad ( 23 )$$

Regarding i_{zvs}(ωt)≈i_{zvs}(π)=I_{zvs,pk} from equations (8) and (9) during δ₃, a linear approximation can be

$$ω ( {C}_{s w 1} + {C}_{s w 3} ) \frac{{V}_{d c}}{{δ}_{3}} = {I}_{zvs , pk} \qquad ( 24 )$$

$$Similarly ,$$

$${δ}_{3} = \frac{8 ω {L}_{ZVS} {C}_{s w}}{{T}_{s}} \qquad ( 25 )$$

For ZVS turn-on of S₃, there is no requirement of i_{load}(t) during δ₃ at all. δ₃ is fully load-independent.

In practice, δ₁ and δ₃ can overlap with each other or contain each other. The rise of vₐ₁ and the fall of v_{b1} can happen at the same time. The fall of vₐ₁ and the rise of v_{b1} can happen at the same time as well.

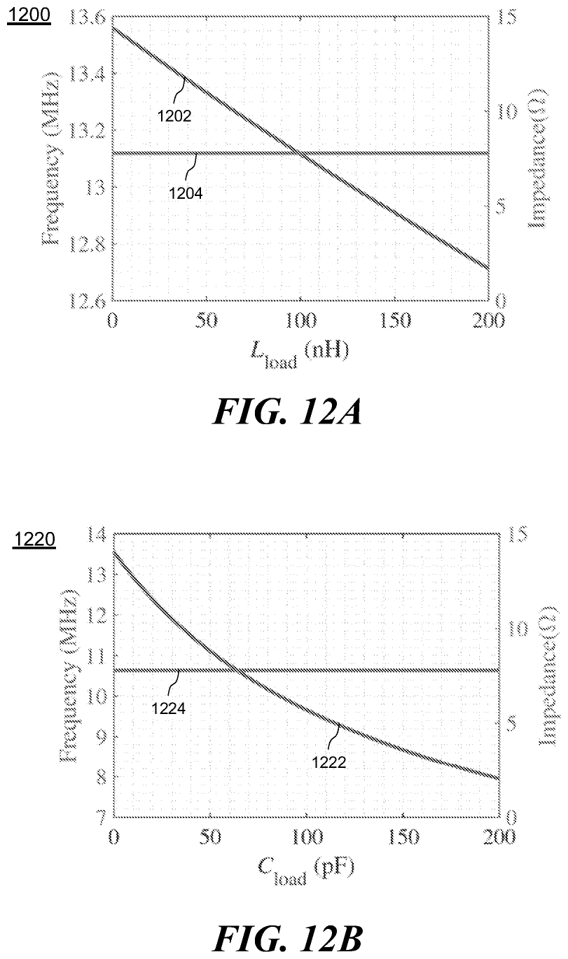

Next describes are techniques for frequency selection/modulation. Because of variable reactive loads, which can be inductive L_{load} as shown in FIG. 8 or capacitive C_{load}, the operating frequency may be selected to keep net reactance Xₙₑₜ formed by the output tank and load reactance constant.

$${X}_{net} = {ω}_{c} ( {L}_{s} - \frac{1}{{ω}_{c}^{2} {C}_{S}} ) = ω ( {L}_{s} - \frac{1}{{ω}^{2} {C}_{s}} ) + {X}_{load} \qquad ( 26 )$$

where X_{load}=ωL_{load} for an inductive load or X_{load}=−1/ωC_{load} for a capacitive load. ω_{c} is the angular center frequency, e.g., 2π×13.56 MHz. The operating frequency

$$\begin{matrix}ω = \frac{{ω}_{c} {L}_{n e t} + \sqrt{{( {ω}_{c} {L}_{n e t} )}^{2} + 4 ( {L}_{s} + {L}_{l o a d} ) / {C}_{s}}}{2 ( {L}_{s} + {L}_{load} )} \\ ω = \frac{{ω}_{c} {L}_{n e t} + \sqrt{{( {ω}_{c} {L}_{n e t} )}^{2} + 4 {L}_{s} / ( {C}_{s} + {C}_{load} )}}{2 {L}_{s}}\end{matrix} \qquad ( 27 )$$

where ω_{c}Lₙₑₜ=ω_{c}Lₛ−1/ω_{c}C₅=Xₙₑₜ, which is used to achieve ZVS of the switches. The frequency selection under L_{load} and C_{load} is shown in FIGS. 12A and 12B, respectively.

FIGS. 12 and 12A illustrate dynamic frequency modulation under different L_{load} and C_{load} for constant Xₙₑₜ. In FIG. 12A, a graph 1200 plots operating frequency 1202 and impedance Xₙₑₜ 1204 as a function of L_{load}. In FIG. 12B, a graph 1220 plots frequency 1222 and impedance Xₙₑₜ 1224 as a function of C_{load}.

The average power owing to the k^{th} harmonic component becomes

$${P}_{k} = \frac{1}{2} {\vert {I}_{k} \vert}^{2} {R}_{load} = \frac{1}{2} \frac{{\vert {V}_{k} \vert}^{2} {R}_{load}}{{X}_{n e t}^{2} + {R}_{load}^{2}} \qquad ( 28 )$$

from equation (7), where we are interested in the dominant component of average power P₁. By selecting operating frequency as equation (27), P₁ in equation (28) is invariant to L_{load} or C_{load} but depends on R_{load}. Also, with high-Q filtering from the output tank, the shape of the relevant operating waveforms remain the same for a given R_{load}.

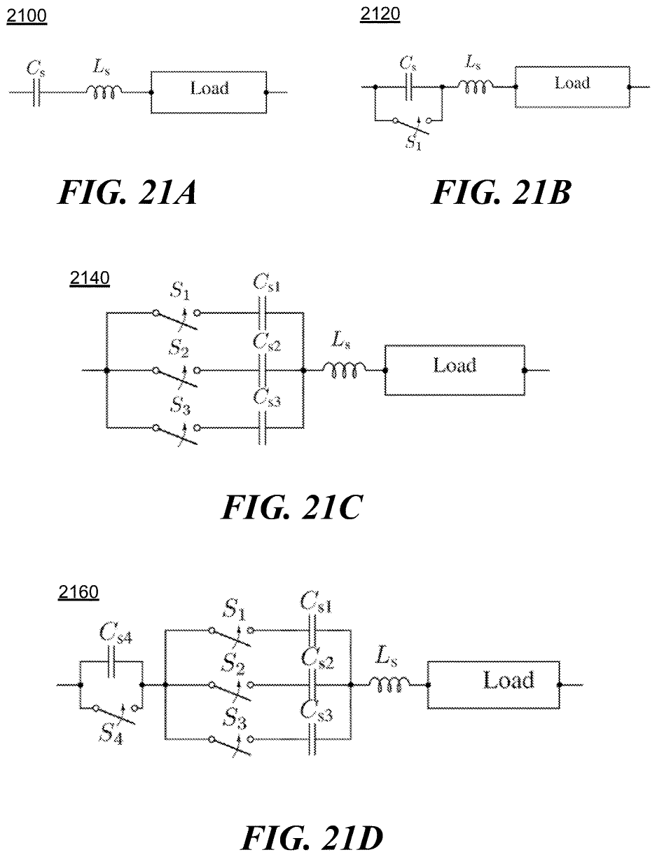

Other modulation methods can be used as well for the series load branch, shown in FIGS. 21A-D, or other frequency selection criteria can be used.

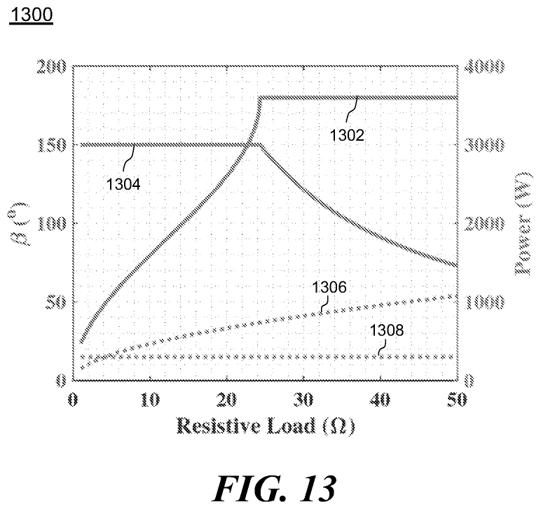

Turning to FIG. 13, initially, one can regard Xₙₑₜ=0Ω, which would be the case if ZVS of the switches were realized with an additional ZVS inductive branch placed in parallel with the output network branch instead of using i_{load} with an inductive Xₙₑₜ. The average power owing to the k^{th} harmonic component becomes

$${P}_{k} = \frac{1}{2} {\vert {I}_{k} \vert}^{2} = \frac{1}{2} \frac{{\vert {V}_{k} \vert}^{2}}{{R}_{load}} \qquad ( 29 )$$

Assuming δ₁=0 and δ₂=0, |Vₖ| in equation (4) becomes equation (1), the average power owing to the k^{th} harmonic component becomes

$${P}_{k} = \frac{1}{2} {\vert {I}_{k} \vert}^{2} = \frac{4}{{k}^{2} {π}^{2}} \frac{{V}_{d c}^{2} [ 1 - cos ( k β ) ]}{{R}_{load}} \qquad ( 30 )$$

Only fundamental power is considered because of high enough quality factor

$${P}_{1} = \frac{4}{{π}^{2}} \frac{{V}_{d c}^{2} ( 1 - cos β )}{{R}_{load}} . \qquad ( 31 )$$

The relationship among P₁, β, and R_{load} is shown in FIG. 13 from (31). FIG. 13 illustrates power P₁, β, resistive load R_{load} relationship for Xₙₑₜ=0, δ₁=0, and δ₂=0. In FIG. 13. Rₘₐₓ=24Ω to have the full power range. In a graph 1300, β is plotted by lines 1302 and 1306, whereas power is plotted by lines 1304 and 1308.

With

$$\begin{matrix}{L}_{s}^{′} / {C}_{s} = {Q}_{min}^{2} \times {R}_{max}^{2} \\ {L}_{s}^{′} {C}_{s} = 1 / {ω}_{c}^{2}\end{matrix} \qquad ( 32 )$$

and Qₘᵢₙ=5, Rₘₐₓ=24Ω, ω_{c}=2φ×13.56 Mrad/s, the result is Lₛ′=1.41 μH and Cₛ=97.8 pF. Lₛ=Lₛ′+Lᵣₑₘₐᵢₙ where Lₙₑₜ=Xₙₑₜ/ω_{c} can be determined to achieve ZVS with C_{sw}=80 pF during δ₂. In some cases, one can select Lₙₑₜ=90 nH.

The resulting quality factor of the output load branch (Lₛ, Cₛ, L_{load}, R_{load}) will be higher than Qₘᵢₙ=5 in equation (32), satisfying the requirement. In some cases, Lₛ and Cₛ may be selected according to a conservative design with respect to the quality factor.

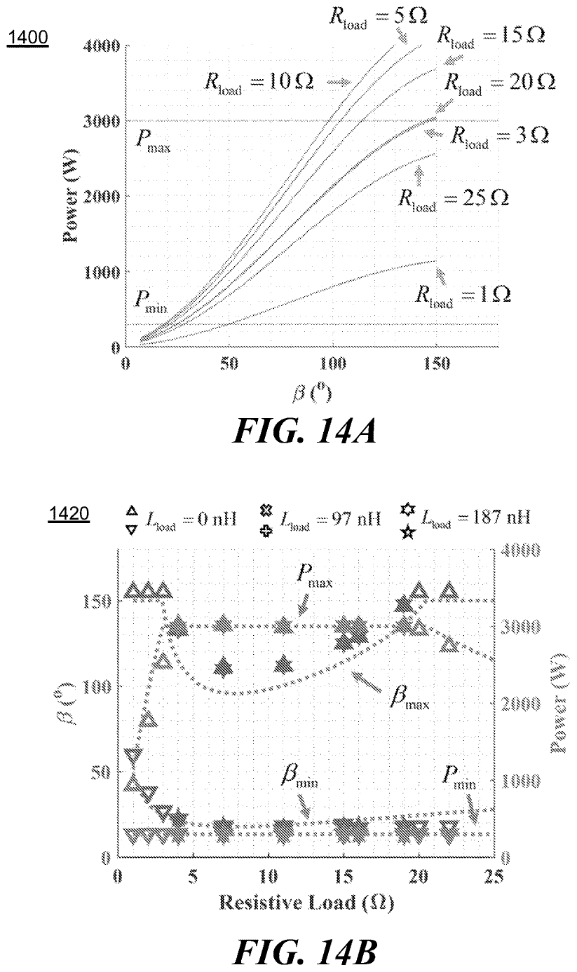

Turning to FIGS. 14A and 14B, given the known variables and requirements, one can plot the relationship among power P₁, β, and R_{load} from equation (7), as shown, considering Xₙₑₜ. FIGS. 14A and 14B illustrate the relationship between power, β, and R_{load} considering Xₙₑₜ, δ₁, and δ₂. Graph 1400 of FIG. 14A shows power range for different β and R_{load} from equation (7). It can be seen that some R_{load} can not achieve the full power range. e.g. R_{load}=1Ω and R_{load}=25Ω. Rₘᵢₙ=3Ω and Rₘₐₓ=20Ω. Graph 1420 of FIG. 14B shows achievable power range for β within the limits under different R_{load}. The single points may come, for example, from simulation with consideration of different L_{load} with dynamic frequency modulation.

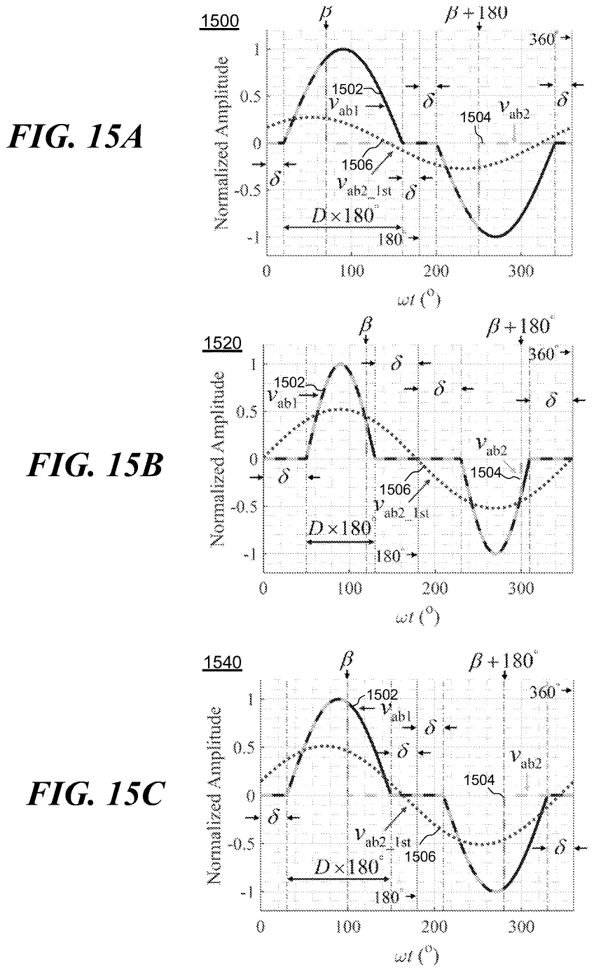

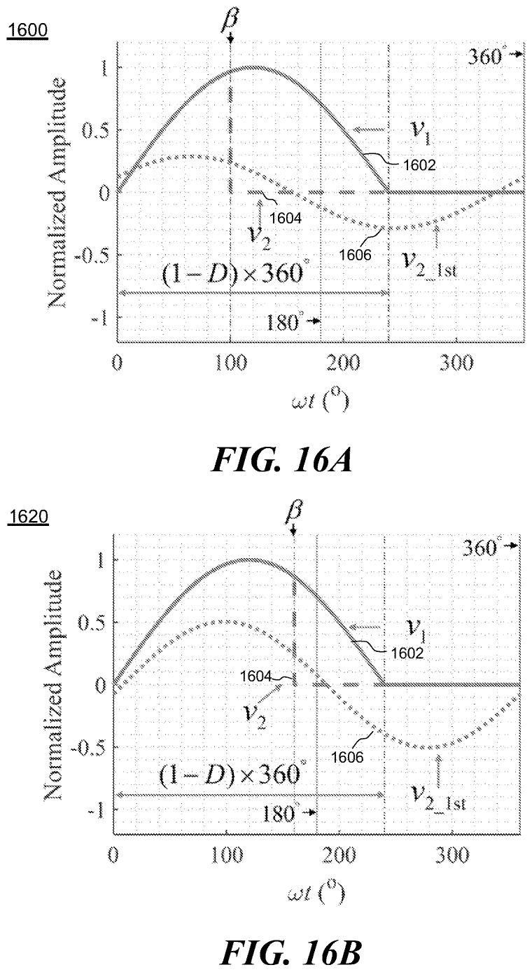

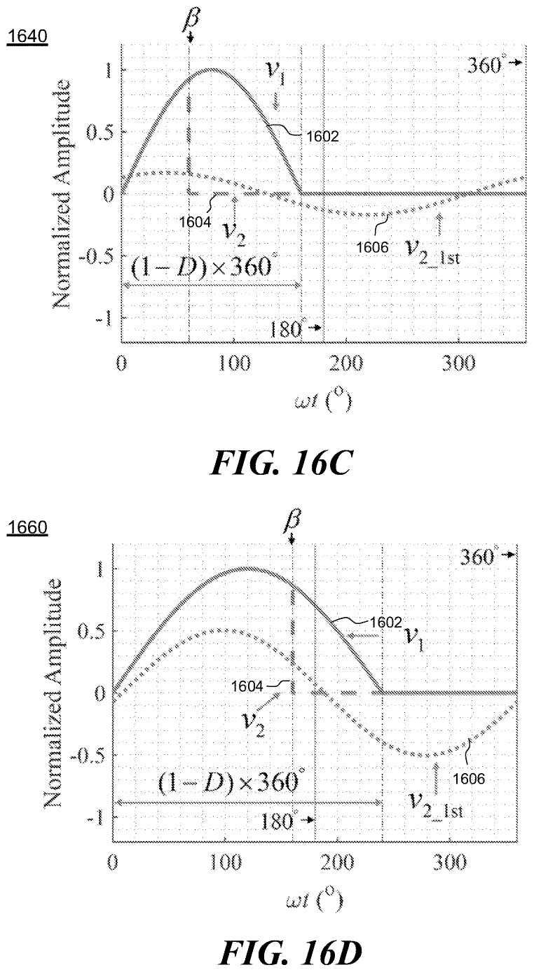

Turning to FIGS. 15A-C, similar to an ideal square-wave or a quasi square-wave, and single polarity square-wave that can be modulated or switched as shown in FIGS. 3, 9, and 7, the sine wave or half-sine wave can also be modulated, which can be shown in FIGS. 15A-C for modulated sine-wave and FIGS. 16A-D for modulated half-sine wave in ideal cases where the fall time at β is instantaneous. Modulated half-sine wave has one more degree of freedom where the half resonant period can be smaller than or larger than 180° while modulated sine wave has to have the half resonant period less than 180°. This is also true for square-wave and single polarity square-wave in six-switch wide-range voltage-mode class-D power amplifier and the three-switch wide-range voltage-mode class-D power amplifier, respectively.

FIGS. 15A-C show modulated sinusoidal waveforms that may be used with a wide-range switched-mode power amplifier, according to some embodiments. Graphs 1500, 1520, and 1540 show examples for three different control angles β, with first intermediate waveform 1502, second intermediate waveform 1504, and sinusoidal output 1506 plotted in each graph. In FIGS. 15A-C, D×180°=180°−2δ, 0<β−δ≤D×180°; v_{ab1}=vₐ₁−v_{b1} and v_{ab2}=vₐ₂−v_{b2}.

FIGS. 16A-D show modulated half-sine waveforms that may be used with a wide-range switched-mode power amplifier, according to some embodiments. Graphs 1600, 1620, 1640, and 1660 show examples for three different control angles δ, with first intermediate waveform 1602, second intermediate waveform 1604, and sinusoidal output 1606 plotted in each graph. In these figures, 0<D<1 and 0<β≤(1−D)×360°; v_{ab1}=vₐ₁−v_{b1} and v_{ab2}=vₐ₂−v_{b2}. In FIG. 16A, (1−D)×360°>180°. In FIG. 16B, (1−D)×360°>180°. In FIG. 16C, (1−D)×360°<180°. In FIG. 16D, (1−D)×360°<180°.

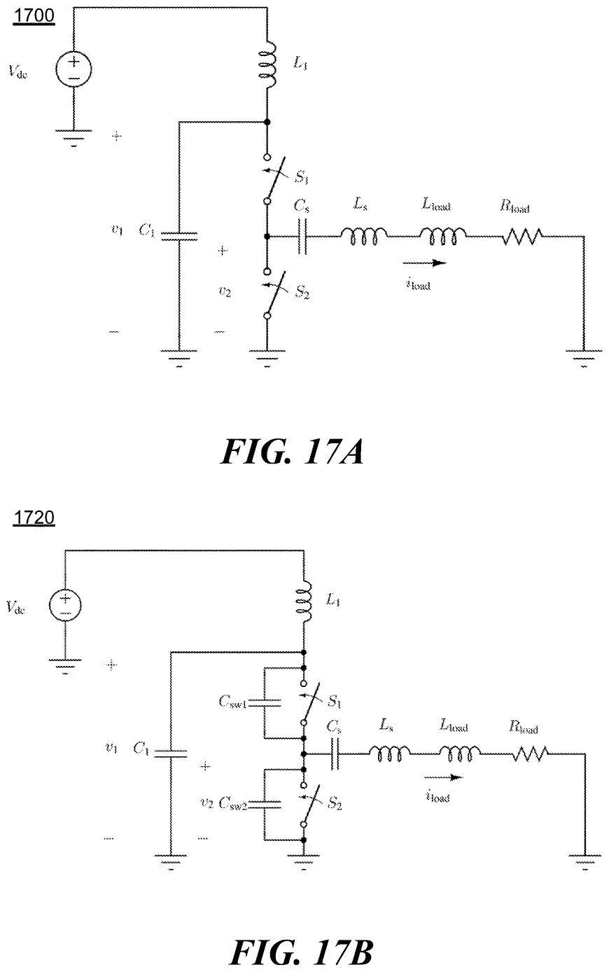

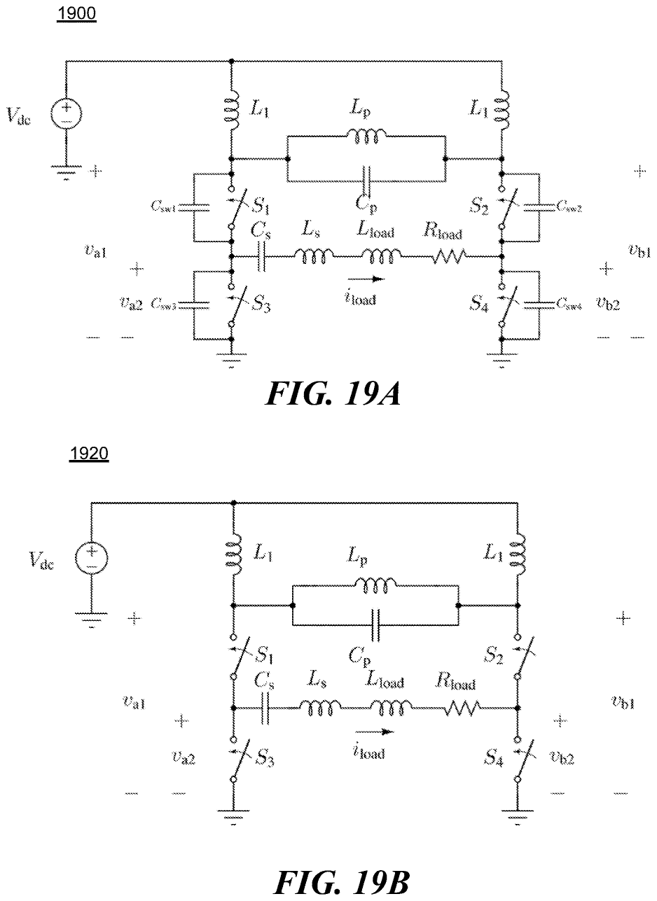

The circuit to achieve the waveform modulation in FIGS. 16A-D can be a wide-range class-E power amplifier, such amplifier 1700 of FIG. 17A and/or amplifier 1720 of FIG. 17B. The circuit to achieve β modulation in FIGS. 15A-C can be a wide-range current-mode class-D power amplifier, as amplifier 1900 of FIG. 19A and/or amplifier 1920 of FIG. 19B. These represent related single-ended and double-ended converter concepts, respectively, just as the single- and double-ended concepts described for the wide-range voltage-mode class-D inverter.

Practically, v₂ cannot goes to zero instantaneously and the switches have switch capacitance C_{sw}. ZVS turn off of v_{a2-b2} and v₂ corresponding switches can be achieved, similar to FIGS. 9 and 11.

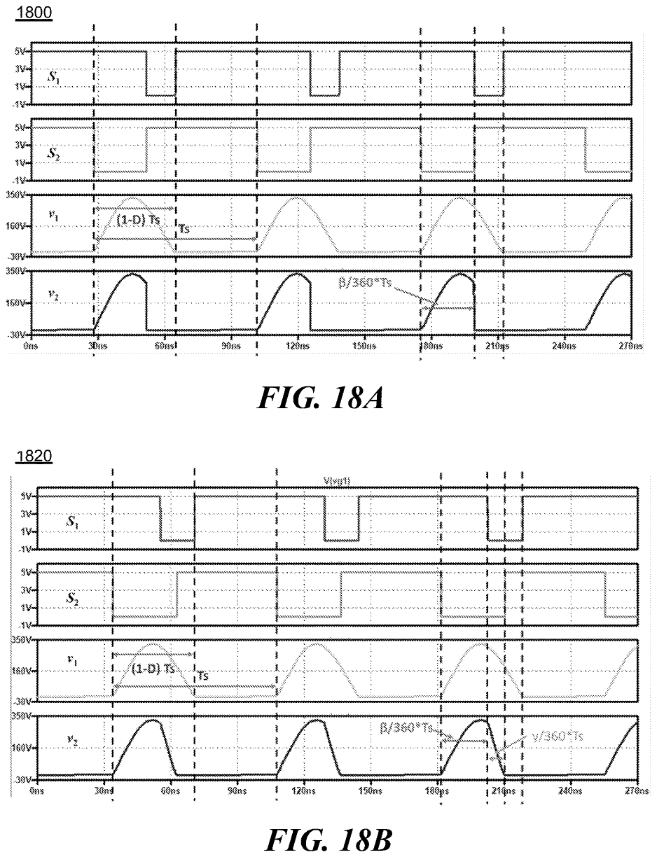

FIGS. 18A and 18B show control sequences and modulated half-sine waveforms, with graph 1800 of FIG. 18A corresponding to an ideal case of the circuit in FIG. 17A with 0<D<1 and 0°<β≤(1−D)×360°, and graph 1820 of FIG. 18B corresponding to a practical case of the circuit in FIG. 17B with 0<D<1 and 0°<β≤(1−D)×360°−γ.

An example of circuit operation of wide-range class-E power amplifiers is that C₁ and L₁ with AND of S₁ and S₂ form a load-independent half-sine wave v₁ first and then S₁ and S₂ modulate v₁ as v₂. Through the series load branch Lₛ, Cₛ, L_{load}, and R_{load}, the load can obtain different power levels based on different duty ratio D, β, and γ (dead time related). FIGS. 18A and 18B shows the control sequences and modulated half-sine waveforms with ideal and practical wide-range class-E power amplifiers shown in FIGS. 17A and 17B with L₁=109.55 nF, C₁=740 pF, C_{sw}=20 pF, Lₛ=1.17 μF, Cₛ=117 pF in simulation.

As part of the operational capability of this approach, variable power can be achieved for a given resistive load or constant power can be achieved for a variable resistive load. Dynamic frequency modulation can be used to deal with reactive loads.

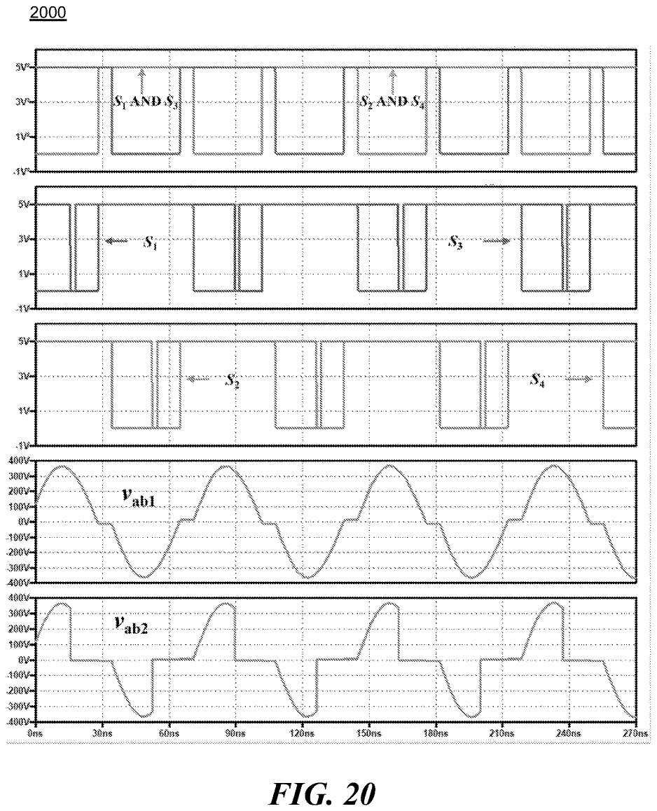

An example of circuit operation of wide-range current-mode class-D power amplifiers is that Cₚ and Lₚ with AND of S₁ and S₃ and AND of S₂ and S₄ form a load-independent sine wave v_{a1_b1} first and then the four switches modulate v_{ab1}(v_{a1-b1})=vₐ₁−v_{b1} as v_{ab2}(v_{a2-b2})=vₐ₂−v_{b2}. Through the series load branch Lₛ, Cₛ, L_{load}, and R_{load}, the load can obtain different power levels based on different duty ratio D and β (neglecting dead time). In FIG. 20, a graph 2000 shows the control sequences and modulated sinusoidal waveforms with ideal wide-range current-mode class-D power amplifiers shown in FIGS. 19A and 19B with Lₚ=97.8 nF, Cₚ=978 pF, C_{sw}=0.1 pF, Lₛ=3.35 μF, Cₛ=46.94 pF in simulation.

As part of the operational capability of this approach, variable power can be achieved for a given resistive load or constant power can be achieved for a variable resistive load. Dynamic frequency modulation can be used to deal with reactive loads.

FIGS. 21A-D illustrate additional or alternative structures and techniques to handle/manage varying load reactance, according to embodiments of the present disclosure. Managing variations in the reactive component of the load impedance can allow for fixed-frequency operation in the face of variable load reactance. As previously discussed, dynamic frequency tuning can be used to manage the effect of varying load reactance, as one example. This is shown by circuit 2100 of FIG. 21A for the series load branch Cₛ, Lₛ, L_{load}, and R_{load}. A switching frequency can be selected that makes the net series reactance posed by the output tank Lₛ, Cₛ, and load inductance Load provide a desired value Xₙₑₜ. As another example, as illustrated by circuit 2120 of FIG. 21B, phase-switched modulation may be used. As another example, as illustrated by circuit 2140 of FIG. 21C, structural modulation may be used (e.g., in the form of a switching network). As another example, as illustrated by circuit 2160 of FIG. 21D, a combination of these techniques may be used (e.g., phase-switch modulation in combination with structural modulation). In some cases, the load branch can also be a parallel branch or a combination of series and parallel branch.

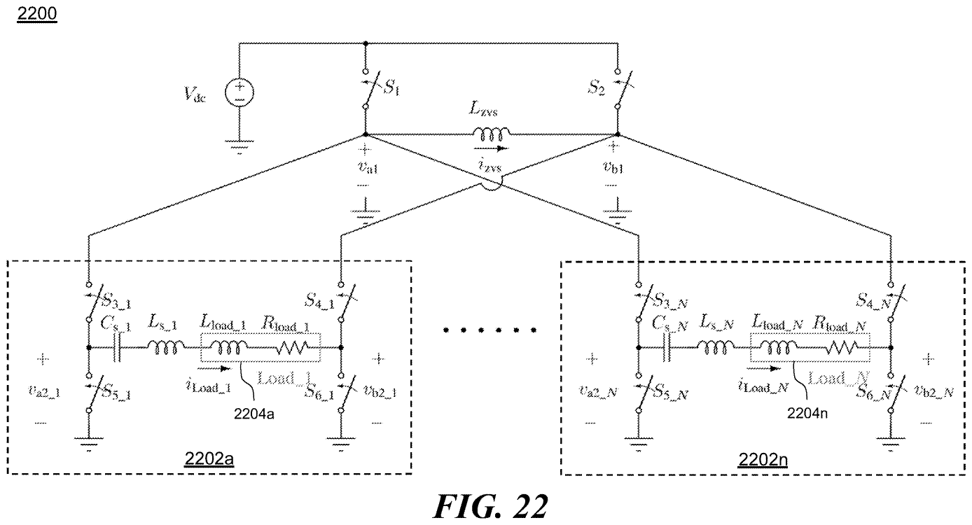

Turning to FIG. 22, the general concepts, structures, and techniques sought to be protected herein can provide for wide-range power amplifiers having multiple output. An illustrative wide-range voltage-mode class-D power amplifier 2200 includes N sets 2202a-n of four switches, with load branches 2204-n arranged in parallel connected to vₐ₁ and v_{b1}. Each set 2202a-n can generate a modulated waveform v_{a2-b2_n} of v_{a1-b1}, as shown in FIGS. 3A-C. Each v_{a2-b2_n} and its fundamental component v_{a2-b2_n_1st} can be the same or different for the same or different series load branch with the same or different C_{s_n}, L_{s_n}, L_{load_n}, and R_{load_n}.

Similarly, other wide-range circuits including six-switch voltage-mode class-D power amplifier (FIGS. 2A, 2B and FIG. 8), three-switch voltage-mode class-D power amplifier (FIGS. 6A, 6B), current-mode class-D power amplifier (FIGS. 19A, 19B), and class-E power amplifier (FIGS. 17A, 17B) can also have multiple output.

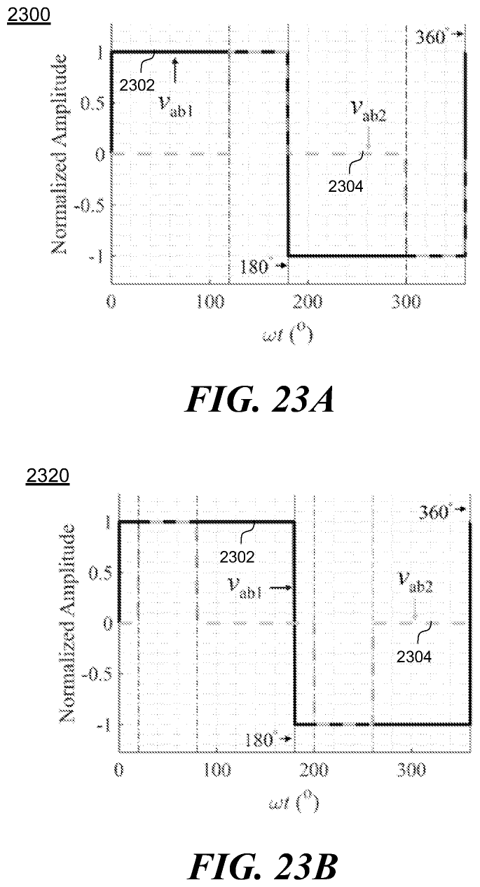

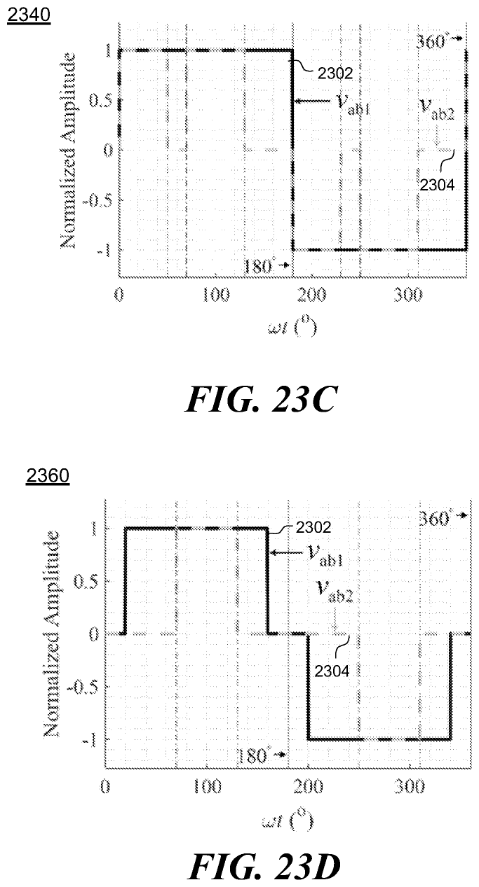

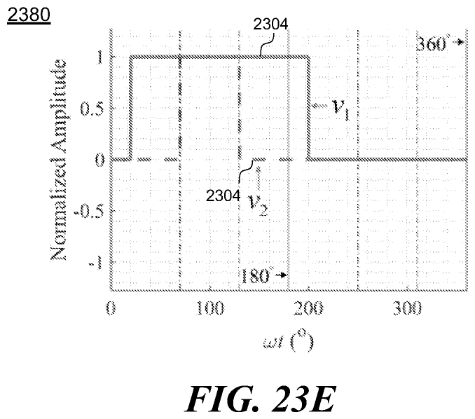

In general, as the β modulation suggests, different zero-state portions or more zero-state portions can be applied to v_{a1-b1} as v_{a2-b2}, as shown in FIGS. 23A-E. Graphs 2300, 2320, 2340, 2360, and 2380 show five different examples of β modulation, with first intermediate 2302 and second intermediate waveform 2304 plotted in each graph. It is still achievable to calculate fundamental component v_{a2-b2_1st} and corresponding load power from different modulated or chopped v_{a2-b2} and corresponding β allocation.

The publication “Wide-range switched-mode power amplifier architecture.” 2023 IEEE 24th Workshop on Control and Modeling for Power Electronics (COMPEL). Ann Arbor, MI. USA. 2023. pp. 1-9, by Xin Zan. Khandoker Nuzhat Rafa Islam, and David Perreault is hereby incorporated by reference in its entirety.

As used herein, the terms “processor” and “controller” are used to describe electronic circuitry that performs a function, an operation, or a sequence of operations. The function, operation, or sequence of operations can be hard coded into the electronic circuit or soft coded by way of instructions held in a memory device. The function, operation, or sequence of operations can be performed using digital values or using analog signals. In some embodiments, the processor or controller can be embodied in an application specific integrated circuit (ASIC), which can be an analog ASIC or a digital ASIC, in a microprocessor with associated program memory, in a digital signal processor (DSP), and/or in a discrete electronic circuit, which can be analog or digital. A processor or controller can include internal processors or modules that perform portions of the function, operation, or sequence of operations. Similarly, a module can include internal processors or internal modules that perform portions of the function, operation, or sequence of operations of the module.

As used herein, the term “predetermined.” when referring to a value or signal, is used to refer to a value or signal that is set, or fixed, in the factory at the time of manufacture, or by external means, e.g., programming, thereafter. As used herein, the term “determined,” when referring to a value or signal, is used to refer to a value or signal that is identified by a circuit during operation, after manufacture.

While electronic circuits shown in figures herein may be shown in the form of analog blocks or digital blocks, it will be understood that the analog blocks can be replaced by digital blocks that perform the same or similar functions and the digital blocks can be replaced by analog blocks that perform the same or similar functions. Analog-to-digital or digital-to-analog conversions may not be explicitly shown in the figures but should be understood.

In the foregoing detailed description, various features are grouped together in one or more individual embodiments for the purpose of streamlining the disclosure. This method of disclosure is not to be interpreted as reflecting an intention that each claim requires more features than are expressly recited therein. Rather, inventive aspects may lie in less than all features of each disclosed embodiment.

References in the disclosure to “one embodiment.” “an embodiment,” “some embodiments,” or variants of such phrases indicate that the embodiment(s) described can include a particular feature, structure, or characteristic, but every embodiment can include the particular feature, structure, or characteristic. Moreover, such phrases are not necessarily referring to the same embodiment(s). Further, when a particular feature, structure, or characteristic is described in connection knowledge of one skilled in the art to affect such feature, structure, or characteristic in connection with other embodiments whether or not explicitly described.

The disclosed subject matter is not limited in its application to the details of construction and to the arrangements of the components set forth in the following description or illustrated in the drawings. The disclosed subject matter is capable of other embodiments and of being practiced and carried out in various ways. As such, those skilled in the art will appreciate that the conception, upon which this disclosure is based, may readily be utilized as a basis for the designing of other structures, methods, and systems for carrying out the several purposes of the disclosed subject matter. Therefore, the claims should be regarded as including such equivalent constructions insofar as they do not depart from the spirit and scope of the disclosed subject matter.

Although the disclosed subject matter has been described and illustrated in the foregoing exemplary embodiments, it is understood that the present disclosure has been made only by way of example, and that numerous changes in the details of implementation of the disclosed subject matter may be made without departing from the spirit and scope of the disclosed subject matter.

All publications and references cited herein are expressly incorporated herein by reference in their entirety.

1. A power amplifier comprising:
a plurality of switches, wherein:
one or more of the switches are configured to generate one or more first intermediate waveforms having one or more first fundamental frequency components, and
one or more of the switches are configured to generate one or more second intermediate waveforms by chopping the one or more first intermediate waveforms with controllable timing, the second intermediate waveforms having one or more second fundamental frequency components that are controllably reduced from those of the one or more first intermediate waveforms; and
an output tank network configured to filter the one or more second intermediate waveforms to provide an output waveform to a load, the output waveform having one or more third fundamental frequency components.

2. The power amplifier of claim 1 wherein the one or more switches are configured to chop the one or more first intermediate waveforms with controllable timing determined by an electrical angle.

3. The power amplifier of claim 1 wherein the one or more of the switches configured to generate the first intermediate waveforms are different from the one or more of the switches configured to generate one or more second intermediate waveforms.

4. The power amplifier of claim 1 wherein the one or more of the switches configured to generate the one or more first intermediate waveforms and the one or more of the switches configured to generate one or more second intermediate waveforms include one or more switches in common.

5. The power amplifier of claim 1 wherein the output tank network comprises a capacitor and inductor connected in series with the load.

6. The power amplifier of claim 1 wherein the plurality of switches comprises at least two switches.

7. The power amplifier of claim 6 wherein the at least two switches are connected in series between a voltage source and ground.

8. The power amplifier of claim 1 wherein the plurality of switches comprises at least six switches.

9. The power amplifier of claim 8 wherein a first three of the at least six switches are connected series between a voltage and ground and wherein at least a second three of the at least six switches are also connected series between a voltage and ground.

10. The power amplifier of claim 1 wherein the one or more first intermediate waveforms comprise one or more square waves.

11. The power amplifier of claim 1 wherein the one or more second intermediate waveforms comprise one or more square waves.

12. The power amplifier of claim 1 wherein the output waveform is a sinusoidal waveform.

13. The power amplifier of claim 1 comprising one or more inductive networks configured to provide zero-voltage switching (ZVS) for the plurality of switches.

14. The power amplifier of claim 13 wherein the one or more inductive networks include the output tank network.

15. The power amplifier of claim 13 wherein the one or more inductive networks include an inductor connected in parallel with the output tank network.

16. The power amplifier of claim 13 wherein the one or more inductive networks include at least two inductive networks.

17. The power amplifier of claim 1 wherein the one or more switches comprise at least four switches arranged as two inverter halves configured to be operated out of phase to provide a second intermediate waveforms taken differentially between the two inverter halves.

18. The power amplifier of claim 1 wherein the one or more second intermediate waveforms comprise at least two second intermediate waveforms combined such that a direct current (DC) component and even harmonics of the at least two second intermediate waveforms cancel and the fundamental components of the at least two second intermediate waveforms reinforce to drive the load.

19. A system comprising:
a power amplifier having:
a plurality of switches, wherein:
one or more of the switches are configured to generate one or more first intermediate waveforms having one or more first fundamental frequency components, and
one or more of the switches are configured to generate one or more second intermediate waveforms by chopping the one or more first intermediate waveforms with controllable timing, the second intermediate waveforms having one or more second fundamental frequency components that are controllably reduced from those of the one or more first intermediate waveforms; and
an output tank network configured to filter one or more second intermediate waveforms to provide an output waveform to a load, the output waveform having one or more third fundamental frequency components; and
a controller configured to control the plurality of switches.

20. The system of claim 19 wherein the controller is configured to use at least one of:
frequency modulation is to adjust for variations in reactance of the load;
frequency modulation to control power, voltage or current delivered to the load; or
beta modulation to control power, voltage or current delivered to the load.
